(19) United States
(12) Patent Application Publication
(10) Pub. No.: US 2015/0303874 A1
(43) Pub. Date: Oct. 22, 2015

(54) DEMODULATOR AND MODULATOR

(71) Applicant: ASAHI KASEI MICRODEVICES CORPORATION, Tokyo (JP)

(72) Inventors: Hiroaki ENOMOTO, Tokyo (JP); Tomoyuki TANABE, Tokyo (JP)

(73) Assignee: ASAHI KASEI MICRODEVICES CORPORATION, Tokyo (JP)

(21) Appl. No.: 14/352,770

(22) PCT Filed: Aug. 16, 2013
(86) PCT No.: PCT/JP13/04880

§ 371 Date: Apr. 18, 2014

(30) Foreign Application Priority Data
Nov. 29, 2012 (JP) 2012-260755

(51) Int. Cl. H03D 7/16; H03C 3/02; H03D 3/02; H04L 27/12; H04L 27/14

(52) U.S. Cl. CPC H03D 7/165; H04L 27/12; H04L 27/14; H03D 3/02; H03C 3/02

(57) ABSTRACT

There is provided a frequency down converter group including frequency down converters corresponding to a plurality of input terminals, and IV converters being paired therewith; and a voltage-controlled oscillating circuit group including voltage-controlled oscillating circuits corresponding to a plurality of frequency bands, and VI converters being paired therewith. The IV converters and VI converters are electrically connected to a common current signal node. The demodulator is capable of generating a local signal having a desired frequency and converting an RF modulated signal into a signal having a frequency of a baseband signal by use of a smaller number of voltage-controlled oscillating circuits, by changing combination of the pair of the operating frequency down converter and the IV converter and the pair of the voltage-controlled oscillating circuit and the VI converter depending on the frequency bands.

### TECHNICAL FIELD

The present invention relates to a demodulator for converting a frequency of an RF modulated signal by using a local signal so as to obtain a baseband modulated signal, and a modulator for converting a frequency of a baseband signal by using the local signal so as to obtain the RF modulated signal.

### BACKGROUND ART

Recently, communication devices represented by cellular telephones are globally used, and acceleration of transmission rate is in progress. Accordingly, frequency bands (bands) used by the communication devices increase and become diverse in every country and each region of the world.

In view of such backgrounds, in order to improve versatility and integration of transmitters and receivers in the communication devices, it is required that the communication device support plural frequency bands (multiple bands) used in a wide range of the countries and regions of the world.

First, the operation of a demodulator in a receiver supporting the multiple bands will be described.

FIG. 9 is a block diagram illustrative of a circuit configuration of a demodulator 100 in a general receiver adopting the direct conversion technology.

As illustrated in FIG. 9, a demodulator 100 includes a frequency down converter 110, a voltage-controlled oscillating circuit 120, and a frequency divider 130.

In the frequency down converter 110, an RF modulated signal received by the demodulator 100 is converted into a signal having a frequency of a baseband signal by use of a local signal as a carrier signal having a carrier frequency of the RF modulated signal, and is outputted as a baseband modulated signal. The local signal received by the frequency down converter 110 is obtained by dividing a frequency of an oscillating signal outputted from the voltage-controlled oscillating circuit 120 in the frequency divider 130.

A possible method to make the demodulator 100 having the above configuration support the multiple bands is to simply prepare the same number of demodulators 100 as the number of the bands.

However, in the case where the number of the bands is numerous, a circuit size is enlarged when the above method is adopted, and also the number of paths connecting the RF modulated signal from an antenna to the demodulator 100 is increased. As a result, the number of mounted components and the like are increased and therefore the method is not practical from an economical viewpoint as well.

On the other hand, since the input impedance matching is relatively easy, enlargement of the circuit size is avoidable by sharing the circuit and the path from the antenna to the frequency down converter for the plural bands having relatively close frequencies, and by configuring the voltage-controlled oscillating circuit to output an oscillating signal having the frequency of a wide range so as to support the carrier frequencies of the plural bands.

A circuit configuration of the demodulator 200 is illustrated in FIG. 10 as an example of the above case.

This demodulator 200 supports the signals of six bands including a band A corresponding to the frequency band around 700 MHz, a band B corresponding to the frequency band around 800 MHz, a band C corresponding to the frequency band around 1.7 GHz, a band D corresponding to the frequency band around 2 GHz, a band E corresponding to the frequency band around 2.3 GHz, and a band F corresponding to the frequency band around 2.5 GHz.

The demodulator 200 includes a frequency down converter A2101, a frequency down converter B2102, a frequency down converter C2103, a voltage-controlled oscillating circuit A2201, a voltage-controlled oscillating circuit B2202, a frequency divider A2301, a frequency divider B2302, and a frequency divider C2303.

The signals of the band A and band B are received as RF modulated signals rf201, and the frequency down converter A2101, the voltage-controlled oscillating circuit A2201, and the frequency divider A2301 are actuated in this case. At this time, the frequency down converter B2102, the frequency down converter C2103, the voltage-controlled oscillating circuit B2202, the frequency divider B2302, and the frequency divider C2303 are stopped.

The signals of the band C and band D are received as RF modulated signals rf202, and the frequency down converter B2102, the voltage-controlled oscillating circuit A2201, and the frequency divider B2302 are actuated in this case. At this time, the frequency down converter A2101, the frequency down converter C2103, the voltage-controlled oscillating circuit B2202, the frequency divider A2301, and the frequency divider C2303 are stopped.

The signals of the band E and band F are received as RF modulated signals rf203, and the frequency down converter C2103, the voltage-controlled oscillating circuit B2202, and the frequency divider C2303 are actuated in this case. At this time, the frequency down converter A2101, the frequency down converter B2102, the voltage-controlled oscillating circuit A2201, the frequency divider A2301, and the frequency divider B2302 are stopped.

The RF modulated signals rf201 of the band A and band B are received by the frequency down converter A2101 and are converted into signals having a frequency of a baseband modulated signal by using local signals sA201 having the frequencies corresponding to the carrier frequencies of the RF modulated signals, and then the converted signals are outputted.

The RF modulated signals rf202 of the band C and band D are received by the frequency down converter B2102 and are converted into signals having the frequency of the baseband modulated signal by using local signals sB202 having the frequencies corresponding to the carrier frequencies of the RF modulated signals, and then the converted signals are outputted.

The RF modulated signals rf203 of the band E and band F are received by the frequency down converter C2103 and are converted into signals having the frequency of the baseband modulated signal by using local signals sC203 having the frequencies corresponding to the carrier frequencies of the RF modulated signal, and then the converted signals are outputted.

The baseband modulated signals outputted from each of the frequency down converters may be outputted through a same shared path or separate paths.

The frequency of the local signal sA201 received by the frequency down converter A2101 is the carrier frequency of the RF modulated signal rf201 of the band A or the band B. The voltage-controlled oscillating circuit A2201 outputs an oscillating signal and the frequency divider A2301 divides the frequency of this oscillating signal such that the local signal sA201 is generated. In the case where a division number of the frequency divider A2301 is “4”, the voltage-controlled oscillating circuit A2201 outputs an oscillating signal having the frequency from approximately 2.8 GHz to approximately 3.2 GHz in order to support the band A and band B.

The frequency of local signal sB202 received by the frequency down converter B2102 is the carrier frequency of the RF modulated signal rf202 of the band C or the band D. The voltage-controlled oscillating circuit A2201 outputs an oscillating signal and the frequency divider B2302 divides the frequency of this oscillating signal such that the local signal sB202 is generated.

In the case where the division number of the frequency divider B2302 is “2”, the voltage-controlled oscillating circuit A2201 may output an oscillating signal having the frequency from approximately 3.4 GHz to approximately 4 GHz in order to support the band C and band D. However, as described above, since the voltage-controlled oscillating circuit A2201 is demanded to support the band A and band B as well, the voltage-controlled oscillating circuit A2201 eventually has to output an oscillating signal having the frequency from approximately 2.8 GHz to approximately 4 GHz.

The frequency of the local signal sC203 received by the frequency down converter C2103 is the carrier frequency of the RF modulated signal rf203 of the band E or the band F. The voltage-controlled oscillating circuit B2202 outputs an oscillating signal and the frequency divider C2303 divides the frequency of this oscillating signal such that the local signal sC203 is generated.

In the case where the division number of the frequency divider C2303 is “2”, the voltage-controlled oscillating circuit B2202 outputs an oscillating signal having the frequency from approximately 4.6 GHz to approximately 5 GHz in order to support the band E and band F.

In the case of integrating the voltage-controlled oscillating circuit A2201 and the voltage-controlled oscillating circuit B2202 in one voltage-controlled oscillating circuit, the one voltage-controlled oscillating circuit has to output an oscillating signal having the frequency from approximately 2.8 GHz to approximately 5 GHz, therefore, there is a problem in that the power consumption increases. Considering the trade-off between the power consumption problem and the size increase of the voltage-controlled oscillating circuit, providing two separate voltage-controlled oscillating circuits is more desirable in most cases as illustrated in FIG. 10.

Next, a modulator in a transmitter supporting the multiple bands will be described.

FIG. 11 is a block diagram illustrative of a circuit configuration of a modulator 300 in a general transmitter adopting the direct conversion technology.

The modulator 300 includes a frequency up converter 310, a voltage-controlled oscillating circuit 320, and a frequency divider 330.

A baseband modulated signal received by the modulator 300 is converted into an RF modulated signal in the frequency up converter 310 by converting the frequency of the baseband signal into a desired frequency of the RF modulated signal by using a local signal corresponding to a carrier frequency of the RF modulated signal, and then the RF signal is outputted. The local signal received by the frequency up converter 310 is obtained by dividing in the frequency divider 330 an oscillating signal outputted from the voltage-controlled oscillating circuit 320.

Here, a possible method to make the modulator support the multiple bands is to simply prepare the same number of the modulators 300 as the number of the bands.

However, as is the case with demodulator 100, in the case where the number of the bands is numerous, the circuit size is enlarged when the method is adopted. Also, the number of paths connecting the RF modulated signal from the modulator to an antenna is increased and, thereby increasing the number of mounted components and the like as well. Therefore, the method is not practical from the economical viewpoint as well.

On the other hand, since the input impedance matching is relatively easy, enlargement of the circuit size is avoidable by sharing the circuit and the path from the frequency up converter 310 to the antenna for the plural bands having relatively close frequencies, and by configuring the voltage-controlled oscillating circuit 320 to output an oscillating signal having the frequency of a wide range so as to support the carrier frequencies of the plural bands.

A circuit configuration of the modulator 400 is illustrated in FIG. 12 as an example of the above case.

This modulator 400 supports the signals of six bands including a band A corresponding to the frequency band around 700 MHz, a band B corresponding to the frequency band around 800 MHz, a band C corresponding to the frequency band around 1.7 GHz, a band D corresponding to the frequency band around 2 GHz, a band E corresponding to the frequency band around 2.3 GHz, and a band F corresponding to the frequency band around 2.5 GHz.

The modulator 400 includes a frequency up converter D4101, a frequency up converter E4102, a frequency up converter F4103, a voltage-controlled oscillating circuit C4201, a voltage-controlled oscillating circuit D4202, a frequency divider D4301, a frequency divider E4302, and a frequency divider F4303.

The band A and band B are outputted as RF modulated signals rf401, and in this case, the frequency up converter D4101, the voltage-controlled oscillating circuit C4201, and the frequency divider D4301 are actuated while the frequency up converter E4102, the frequency up converter F4103, the voltage-controlled oscillating circuit D4202, the frequency divider E4302, and the frequency divider F4303 are stopped.

The band C and band D are outputted as RF modulated signals rf402, and in this case, the frequency up converter E4102, the voltage-controlled oscillating circuit C4201, and the frequency divider E4302 are actuated while the frequency up converter D4101, the frequency up converter F4103, the voltage-controlled oscillating circuit D4202, the frequency divider D4301, and the frequency divider F4303 are stopped.

The band E and band F are outputted as RF modulated signals rf403, and in this case, the frequency up converter F4103, the voltage-controlled oscillating circuit D4202, and the frequency divider F4303 are actuated while the frequency up converter D4101, the frequency up converter E4102, the voltage-controlled oscillating circuit C4201, the frequency divider D4301, and the frequency divider E4302 are stopped.

The RF modulated signals rf401 of the band A and band B are generated in the frequency up converter D4101. More specifically, in the frequency up converter D4101, the baseband modulated signals are converted into signals having the frequencies of the RF modulated signals rf401 by using local signals sD401, and then the converted signals are outputted as the RF modulated signals rf401.

The RF modulated signals rf402 of the band C and band D are generated in the frequency up converter E4102. More specifically, in the frequency up converter E4102, the baseband modulated signals are converted into signals having the frequencies of the RF modulated signals rf402 by using a local signals sE402, and then the converted signals are outputted as the RF modulated signals rf402.

The RF modulated signals rf403 of the band E and band F are generated in the frequency up converter F4103. More specifically, in the frequency up converter F4103, the baseband modulated signal are converted into signals having the frequencies of the RF modulated signals rf403 by using a local signals sF403, and then the converted signals are outputted as the RF modulated signals rf403.

The baseband modulated signals received by each of the frequency up converters may be received from the same path or separate paths.

The frequency of the local signal sD401 received by the frequency up converter D4101 is the carrier frequency of the RF modulated signal rf401 of the band A or band B. The voltage-controlled oscillating circuit C4201 outputs an oscillating signal and the frequency divider D4301 divides the frequency of this oscillating signal such that the local signal sD401 is generated. In the case where a division number of the frequency divider D4301 is “4”, the voltage-controlled oscillating circuit C4201 outputs an oscillating signal having the frequency from approximately 2.8 GHz to approximately 3.2 GHz, in order to support the band A and band B.

The frequency of the local signal sE402 received by the frequency up converter E4102 is the carrier frequency of the RF modulated signal rf402 of the band C or band D. The voltage-controlled oscillating circuit C4201 outputs an oscillating signal and the frequency divider E4302 divides the frequency of this oscillating signal such that the local signal sE402 is generated.

In the case where the division number of the frequency divider E4302 is “2”, the voltage-controlled oscillating circuit C4201 may output an oscillating signal having the frequency from approximately 3.4 GHz to approximately 4 GHz, in order to support the band C and band D. However, since the voltage-controlled oscillating circuit C4201 is demanded to support the band A and band B as well, the voltage-controlled oscillating circuit A4201 outputs an oscillating signal having the frequency from approximately 2.8 GHz to approximately 4 GHz.

The frequency of the local signal sF403 received by the frequency up converter F4103 is the carrier frequency of the RF modulated signal rf403 of the band E or band F. The voltage-controlled oscillating circuit D4202 outputs an oscillating signal and the frequency divider F4303 divides the frequency of this oscillating signal such that the local signal sF403 is generated.

In the case where the division number frequency divider F4303 is “2”, the voltage-controlled oscillating circuit D4202 outputs an oscillating signal having the frequency from approximately 4.6 GHz to approximately 5 GHz, in order to support the band E and band F.

As is the case with the demodulator 200, it is also more desirable in most cases, that the voltage-controlled oscillating circuit C4201 and the voltage-controlled oscillating circuit D4202 are separated in the modulator 400.

FIG. 13 is illustrative of an example of band combinations used in two regions including region a and region b with regard to the signals of the six bands including the band A of the frequency around 700 MHz, band B of the frequency around 800 MHz, band C of the frequency around 1.7 GHz, band D of the frequency around 2 GHz, band E of the frequency around 2.3 GHz, and band F of the frequency around 2.5 GHz.

The bands A, C, and E are used in the region a, and the bands B, D and F are used in the region b.

In the above example of the demodulator 200 illustrated in FIG. 10, the RF modulated signals of the respective band A, band C and band E are received by respective input terminals T201, T202 and T203. In the modulator 400 illustrated in FIG. 12, the RF modulated signals of the respective band A, band C and band E are outputted from respective output terminals T401, T402 and T403. Therefore, a communication device having a set of the demodulator 200 and the modulator 400 supports all of the bands in the region a.

In the same manner, in the demodulator 200, the signals of the respective band B, band D and band F are received by the respective input terminals T201, T202, and T203. In the modulator 400, the RF modulated signals of the respective band B, band D and band F are outputted from the respective output terminals T401, T402 and T403. Therefore, a communication device having the set of the demodulator 200 and the modulator 400 supports all of the bands in the region b.

In short, when a communication device having one set of the demodulator 200 and the modulator 400 is provided, all of the bands used in the respective regions a and b are supported in both of the regions a and b.

Next, consideration will be given for a case in which the receiver including the demodulator 200 illustrated in FIG. 10 and the transmitter including the modulator 400 illustrated in FIG. 12 are demanded to support an increased number of regions.

FIG. 14 is illustrative of an example of band combinations used in the region a, the region b and the region c.

The bands used in the region a and the region b are the same as those illustrated in FIG. 13, but in the region c, the bands A, C, D and F are additionally used. As described above, in the demodulator 200 illustrated in FIG. 10 and in the modulator 400 illustrated in FIG. 12, the RF modulated signals of the band C and band D are received by the shared input terminal T202, and outputted from the output terminal T402, and processed by the shared frequency down converter B2102 or the frequency up converter E4102. Accordingly, an additional circuit for separately processing the RF modulated signal of the band C and the RF modulated signal of the band D is needed in order to support the bands A, C, D and F.

Here, the mounted components such as a duplexer may hardly be shared between the band C and the band D. Accordingly, the signal of the band C and the band D are needed to be received or outputted in a separate manner in order to support all of the bands used in the region c. More specifically, two separate input terminals T202 of the demodulators 200 and two separate output terminals T402 of the modulators 400 are needed for the bands C and D.

Meanwhile, it is necessary to support the region a and the region b. As a result, at least four sets of the input terminals of the demodulators 200 and at least four sets of output terminals of the modulators 400 are needed.

FIG. 15 is illustrative of a list of the bands corresponding to the respective four sets of the input terminals or the output terminals (hereinafter also referred to as input/output terminal) in order to support all of the bands used in each of the region a, the region b and the region c illustrated in FIG. 14 by use of the four sets of the input terminals and the output terminals.

For instance, the input/output terminal T1 is provided to support the band A and the band B, the input/output terminal T2 is provided to support the band C, the input/output terminal T3 is provided to support the band D and band E, and the input/output terminal T4 is provided to support the band F.

If the respective input/output terminal is associated with the respective bands as described above, in the case where the communication device having the demodulator 200 and the modulator 400 is used, for example, in the region a, the input/output terminal T1 is associated with the band A, the input/output terminal T2 is associated with the band C, and the input/output terminal T3 is associated with the band E.

The input/output terminal T4 is not used. In the case of using in the region b, the input/output terminal T1 is associated with the band B, the input/output terminal T3 is associated with the band D, and the input/output terminal T4 is associated with the band F. The input/output terminal T2 is not used. In the case of using in the region c, the input/output terminal T1 is associated with the band A, the input/output terminal T2 is associated with the band C, the input/output terminal T3 is associated with the band D, and the input/output terminal T4 is associated with the band F.

With the above association, the communication device having the demodulator 200 and the modulator 400 is usable in the respective regions a to c.

Further, as an example of the above described communication device, another communication device is proposed in which the increase of the voltage-controlled oscillating circuit is avoided by setting the division number of the frequency divider used in the demodulator 200 or the modulator 400 at a value other than an integer (see PTL 1, for example).

In the example in which the communication device having the demodulator 200 and the modulator 400 is configured to support the bands used in the region a, the region b and the region c illustrated in FIG. 14, the division number of the frequency divider generating the local signal corresponding to the band E is set to “2”, and the division number of the frequency divider generating the local signal corresponding to the band D is set to “2.5”. By thus setting, the frequency before dividing the frequency becomes 4.6 GHz for the band E, and 5 GHz for the band D. Therefore, both signals having these frequencies can be obtained from the same voltage-controlled oscillating circuit.

### CITATION LIST

### Patent Literature

PTL 1: JP 2009-147790 A

### SUMMARY OF INVENTION

### Technical Problem

However, a phase difference between two sets of local signals obtained by the frequency divider having the division number other than an integer is not 90 degrees. Therefore, the signals are not usable for demodulating or modulating of an IQ orthogonal modulated signal as they are. Accordingly, an additional circuit is needed for changing this phase difference to 90 degrees. In such a case, the area of the circuit is increased by the area of the additional circuit for adjusting the phase difference, and the power consumption of the circuit is increased by the power consumption of the additional circuit. Furthermore, there is a problem in that characteristics, such as noise power characteristics, are deteriorated.

On the other hand, in the case of adopting the circuit configuration according to the related art in which the division number is set to an even number so that the phase difference between the two sets of local signals outputted from the frequency divider becomes 90 degrees without any adjustment, there are problems in that the area of the circuit is inevitably increased by adding the voltage-controlled oscillating circuit, or the power consumption in the voltage-controlled oscillating circuit is inevitably increased in order to obtain sufficiently low noise power because the output load of the voltage-controlled oscillating circuit is increased.

FIG. 16 is illustrative of a circuit configuration of a demodulator 500 in which one voltage-controlled oscillating circuit is added to the demodulator 200 illustrated in FIG. 10 so as to support all of the bands used in the respective region a, region b and region c illustrated in FIG. 14.

The demodulator 500 includes the demodulator 100 illustrated in FIG. 9 and the demodulator 200 illustrated in FIG. 10. As described above, the demodulator 200 supports the multiple bands.

In this demodulator 500, an RF modulated signal rf501 of the band A or the band B is received by the frequency down converter A2101 of the demodulator 200, an RF modulated signal rf502 of the band C is received by the frequency down converter B2102 of the demodulator 200, and an RF modulated signal rf503 of the band F is received by the frequency down converter C2103 of the demodulator 200. An RF modulated signal rf504 of the band D and the band E is supported by use of the demodulator 100. The voltage-controlled oscillating circuit 120 of the demodulator 100 outputs an oscillating signal having the frequency from approximately 4 GHz to approximately 4.6 GHz which is twice the carrier frequency of the band D and the band E.

With this configuration, the regions a to c is supported by the demodulator 500.

However, in the case of adding the demodulator simply by the number of the input terminals for receiving the RF modulated signal of the added band as illustrated in FIG. 16, the number of the demodulator 100 is increased in accordance with the increased number of the bands in FIG. 16. More specifically, the voltage-controlled oscillating circuit 120 is added even though the signal having the frequency around 4 GHz can be generated in the voltage-controlled oscillating circuit A2201 in the demodulator 200 and the signal having the frequency around 4.6 GHz can be generated in the voltage-controlled oscillating circuit B2202 in the demodulator 200. Therefore, there is a problem in that the area of the circuit is undesirably increased by the amount of the added voltage-controlled oscillating circuit 120 which is not basically needed to be added.

Further, there is another possible method instead of adding only the voltage-controlled oscillating circuit 120 to the demodulator 100, in which either an output signal of the voltage-controlled oscillating circuit A2201 or an output signal of the voltage-controlled oscillating circuit B2202 is selected to be received by the frequency divider 130 of the demodulator 100 depending on whether RF modulated signal of the band D or that of the band E is received.

However, in the above case, when a switch composed of a transistor or the like is added for selecting the output signal of the voltage-controlled oscillating circuit, the output load of the voltage-controlled oscillating circuit is increased. Therefore, characteristics deterioration is inevitably caused, such as decrease of an output amplitude, reduction of an oscillation frequency range and increase of the noise power. As a result, the power consumption is increased to compensate such characteristics deterioration.

Also, there may be another possible method instead of adding the voltage-controlled oscillating circuit 120, in which either an output signal of the frequency divider B2302 or an output signal of the frequency divider C2303 in the demodulator 200 is selected depending on whether the RF modulated signal of the band D or that of the band E is received, and the selected output signal is received by the frequency down converter 110 of the demodulator 100.

However, in this case also, when the switch composed of the transistor or the like is added for selecting the output signal of the frequency divider, the output load of the frequency divider is increased. Therefore, characteristics deterioration is inevitably caused, such as decrease of the output amplitude, reduction of the dividable frequency range and increase of the noise power. As a result, the power consumption is increased to compensate such characteristics deterioration.

In addition, in the case of adopting a method in which separate demodulators are prepared to have the two separate input terminals for receiving the RF modulated signal of the band D and the RF modulated signal of the band E, both band D and band E are supported without adding the voltage-controlled oscillating circuit.

However, in this case, there is a problem in that the frequency down converters, the frequency dividers, and the circuit needed between the antenna and the frequency down converter are increased, thus, the area of the circuit is increased.

Further, assuming that the input terminals are increased, the same measures as the related art increases the sets of the frequency down converter and the frequency divider. Accordingly, the number of the frequency divider connected to the voltage-controlled oscillating circuit is increased. Consequently, an extra capacity load is added to the output of the voltage-controlled oscillating circuit, and there are caused problems in characteristic, such as problems in the power consumption and noise power.

FIG. 17 is illustrative of a circuit configuration of a modulator 600 in which one voltage-controlled oscillating circuit is added to the modulator 400 illustrated in FIG. 12 to support all of the bands used in the respective region a, region b, and region c illustrated in FIG. 14.

The modulator 600 includes the modulator 300 illustrated in FIG. 11 and the modulator 400 illustrated in FIG. 12. As described above, the modulator 400 supports the multiple bands. In this modulator 600, an RF modulated signal rf601 of the band A or the band B is outputted from a frequency up converter D4101 of the modulator 400, an RF modulated signal rf602 of the band C is outputted from a frequency up converter E4102 of the modulator 400, and an RF modulated signal rf603 of the band F is outputted from a frequency up converter F4103 of the modulator 400.

The modulator 300 supports the RF modulated signals rf604 of the band D and the band E. More specifically, a voltage-controlled oscillating circuit 320 in the modulator 300 outputs oscillating signals having the frequencies from approximately from 4 GHz to approximately 4.6 GHz, which are twice the carrier frequencies of the band D and the band E.

Thus, in the case of adding the modulator simply by the number of the output terminal for outputting the RF modulated signal of the increased band, as is the case with the above demodulator 500, the voltage-controlled oscillating circuit 320 is added even though the signal having the frequency around 4 GHz can be generated in the voltage-controlled oscillating circuit C4201 of the modulator 400 and the signal having the frequency around 4.6 GHz can be generated in the voltage-controlled oscillating circuit D4202 of the modulator 400. Therefore, there is a problem in that the area of the circuit is undesirably increased by the added voltage-controlled oscillating circuit 320 not needed basically.

Also, as is the case with the demodulator 500, the method of selecting any of the outputs of the voltage-controlled oscillating circuits or selecting any of the outputs of the frequency dividers is selected in modulator 400, depending on whether the RF modulated signal of the band D or that of the band E is received can be adopted, instead of adding the voltage-controlled oscillating circuit 320. In this method, however, characteristics of the voltage-controlled oscillating circuit or the frequency divider are deteriorated. As a result, the power consumption is increased to compensate such characteristics deterioration.

Similarly, in the case of preparing the separate output terminals for outputting the RF modulated signal of the band D and the RF modulated signal of the band E, there is a problem in that the frequency up converter, the frequency divider, and the circuit needed between the frequency up converter to the antenna are increased, thus the area of the circuit is increased.

Moreover, assuming that the output terminals are increased, the same measures as the related art increases the number of the sets of the frequency up converter and the frequency divider. Accordingly, the number of the frequency dividers connected to the voltage-controlled oscillating circuits is increased. Consequently, extra load is added to the output of the voltage-controlled oscillating circuit, and there are caused problems in the characteristics, such as problems in power consumption and noise power.

As described above, in the demodulator and the modulator supporting the multiple bands, when the input terminals or the output terminals are increased along with the increase of the bands to be supported, and the frequency divider having a division number other than an integer is used, there is a problem for demodulating or modulating the IQ orthogonal modulated signal, in that the circuit area and power consumption are increased, and the characteristics such as the noise power characteristics is deteriorated, even though the voltage-controlled oscillating circuit is not added.

Furthermore, in the case of adopting the method in the related art in which the division number of the frequency divider is set to an even number, there are caused problems in that the area of the circuit is increased along with the increase of the voltage-controlled oscillating circuit. And there are caused the characteristics problems such as increase of the power consumption or increase of the noise power, because the output capacity load of the voltage-controlled oscillating circuit is increased due to the increase of the frequency divider along with the increase of the input terminals and the output terminals.

The present invention is achieved in view of the above problems, and the object of the present invention is to provide a demodulator and a modulator supporting the multiple bands and suppressing the needed number of the voltage-controlled oscillating circuit and the frequency divider even in the case where the input terminal and the output terminal are newly added, and further, being capable of modulating and demodulating the IQ orthogonal modulated signal without increasing the output loads of the voltage-controlled oscillating circuit and the frequency divider even though the input terminal and output terminal are increased.

### Solution to Problem

According to an aspect of the present invention, there is provided a demodulator, including: a frequency down conversion unit (for example, a frequency down converter group 11 illustrated in FIG. 1) including a plurality of input terminals (for example, input terminals T11 to T1K illustrated in FIG. 1) at which a plurality of RF modulated signals is received, respectively, a plurality of frequency down converters (for example, frequency down converters 111 to 11K illustrated in FIG. 1) provided for the plurality of input terminals, respectively, and a plurality of IV converters (for example, IV converters 121 to 12K illustrated in FIG. 1) provided for the plurality of frequency down converters, respectively; a voltage-controlled oscillation unit (for example, a voltage-controlled oscillating circuit group 13 illustrated in FIG. 1) including a plurality of voltage-controlled oscillating circuits (for example, a voltage-controlled oscillating circuits 131 to 13L illustrated in FIG. 1) and a plurality of VI converters (for example, VI converters 141 to 14L illustrated in FIG. 1) provided for the plurality of voltage-controlled oscillating circuits, respectively; and a node (for example, a current signal node N10 illustrated in FIG. 1) electrically connected to the plurality of IV converters and the plurality of VI converters.

One IV converter among the plurality of IV converters may receive a current signal from one VI converter among the plurality of VI converters via the node, the one IV converter being paired with one of the plurality of frequency down converters corresponding to one of the plurality of input terminals at which the RF modulated signal is received, the one VI converter being paired with one of the plurality of voltage-controlled oscillating circuits for generating a voltage signal having a frequency corresponding to the received RF modulated signal.

The demodulator may include a control unit (for example, a control unit 15 illustrated in FIG. 1) configured to output a control signal. The control signal may actuate the one IV converter among the plurality of IV converters and the one VI converter among the plurality of VI converters, the one IV converter being paired with the one of the plurality of frequency down converters corresponding to the one of the plurality of input terminals at which the RF modulated signal is received, the one VI converter being paired with the one of the plurality of voltage-controlled oscillating circuits for generating the voltage signal having the frequency corresponding to the received RF modulated signal. The control signal may stop an IV converter other than the one IV converter among the plurality of IV converters and a VI converter other than the one VI converter among the plurality of VI converters.

The plurality of RF modulated signals may have different frequency bands, respectively.

The plurality of voltage-controlled oscillating circuits may generate voltage signals having carrier frequencies corresponding to respective frequency bands of the plurality of RF modulated signals received by the frequency down conversion unit or frequencies corresponding to an even multiple of the carrier frequencies.

The plurality of IV converter may include a first IV conversion unit (for example, IV converters B222, C223 and D224 illustrated in FIG. 2) configured to reduce a frequency of the current signal to half, and a second IV conversion unit (for example, an IV converter A221 illustrated in FIG. 2) configured to reduce the frequency of the current signal to quarter.

The plurality of voltage-controlled oscillating circuits may include a first voltage-controlled oscillating circuit and a second voltage-controlled oscillating circuit configured to generate voltage signals having frequencies of different bands, respectively. The plurality of input terminals may include at least one input terminal, the RF modulated signals of two or more frequency bands being received at each of the at least one input terminal. The first voltage-controlled oscillating circuit may generate the voltage signal having a carrier frequency corresponding to a frequency band of a first RF modulated signal or a frequency corresponding to an even multiple of the carrier frequency. The second voltage-controlled oscillating circuit may generate the voltage signal having a carrier frequency corresponding to a frequency band of a second RF modulated signal or a frequency corresponding to an even multiple of the carrier frequency.

According to another aspect of the present invention, there is provided a modulator including: a frequency up conversion unit (for example, a frequency up converter group 31 illustrated in FIG. 3) including a plurality of output terminals (for example, output terminals T31 to T3K illustrated in FIG. 3) for outputting a plurality of RF modulated signals, respectively, a plurality of frequency up converters (for example, frequency up converters 311 to 31K illustrated in FIG. 3) provided for the plurality of output terminals, respectively, and a plurality of IV converters (for example, IV converters 321 to 32K illustrated in FIG. 3) provided for the plurality of frequency up converters, respectively; a voltage-controlled oscillation unit (for example, a voltage-controlled oscillating circuit group 33 illustrated in FIG. 3) including a plurality of voltage-controlled oscillating circuits (for example, voltage-controlled oscillating circuits 331 to 33L illustrated in FIG. 3) and a plurality of VI converters (for example, VI converters 341 to 34L illustrated in FIG. 3) provided for the plurality of voltage-controlled oscillating circuits, respectively; and a node (for example, a current signal node N30 illustrated in FIG. 3) electrically connected to the plurality of IV converters and the plurality of VI converters.

One IV converter among the plurality of IV converters may receive a current signal from one VI converter among the plurality of VI converters via the node, the one IV converter generating a local signal having a frequency corresponding to the RF modulated signal to be outputted, the one VI converter being paired with one of the plurality of voltage-controlled oscillating circuits for generating a voltage signal having a frequency corresponding to the RF modulated signal to be outputted.

The modulator may include a control unit (for example, a control unit 35 illustrated in FIG. 3) configured to output a control signal. The control signal may actuate the one IV converter among the plurality of IV converters and the one VI converter among the plurality of VI converters, the one IV converter generating the local signal having the frequency corresponding to the RF modulated signal to be outputted, the one VI converter being paired with the one of the plurality of voltage-controlled oscillating circuits for generating the voltage signal having the frequency corresponding to the RF modulated signal to be outputted. The control signal may stop an IV converter other than the one IV converter among the plurality of IV converters and a VI converter other than the one VI converter among the plurality of VI converters.

The plurality of RF modulated signals may have different frequency bands, respectively.

The plurality of voltage-controlled oscillating circuits may generate voltage signals having carrier frequencies corresponding to respective frequency bands of all of the RF modulated signals to be outputted from the frequency up conversion unit or frequencies corresponding to an even multiple of the carrier frequencies.

The plurality of IV converter may include a first IV conversion unit (for example, IV converters F422, G423, H424 illustrated in FIG. 4) configured to reduce a frequency of the current signal to half, and a second IV conversion unit (for example, an IV converter E421 illustrated in FIG. 4) configured to reduce the frequency of the current signal to quarter.

The plurality of voltage-controlled oscillating circuits may include a first voltage-controlled oscillating circuit and a second voltage-controlled oscillating circuit configured to generate voltage signals having frequencies of different bands, respectively. The plurality of output terminals may include at least one output terminal, the RF modulated signals of two or more frequency bands being outputted at each of the at least one output terminal. The first voltage-controlled oscillating circuit may generate the voltage signal having a carrier frequency corresponding to a frequency band of a first RF modulated signal or a frequency corresponding to an even multiple of the carrier frequency. The second voltage-controlled oscillating circuit may generate the voltage signal having a carrier frequency corresponding to a frequency band of a second RF modulated signal or a frequency corresponding to an even multiple of the carrier frequency.

### Advantageous Effects of Invention

According to the present invention, even in the case where the input terminal or the output terminal is newly added in the demodulator or the modulator supporting the multiple bands, it is possible to suppress the increase of the voltage-controlled oscillating circuit and the frequency divider. Further, it is possible to suppress the increase of the output loads of voltage-controlled oscillating circuit and frequency divider even in the case where the input terminal and output terminal are added.

### BRIEF DESCRIPTION OF DRAWINGS

FIG. 1 is an exemplary functional block diagram illustrative of a demodulator according to an embodiment of the present invention;

FIG. 2 is an exemplary functional block diagram of the demodulator illustrated in FIG. 1 in the case where K=4 and L=2;

FIG. 3 an exemplary functional block diagram illustrative of a modulator according to an embodiment of the present invention;

FIG. 4 is an exemplary functional block diagram of the modulator illustrated in FIG. 3 in the case where K=4 and L=2;

FIG. 5 is a circuit diagram illustrative of an exemplary configuration of the VI converter illustrated in FIGS. 2 and 4 implemented by transistors;

FIG. 6 is a circuit diagram illustrative of an exemplary configurations of an IV converter B222, an IV converter C223 and an IV converter D224 illustrated in FIG. 2 and an IV converter F422, an IV converter G423 and an IV converter H424 illustrated in FIG. 4 implemented by transistors;

FIG. 7 is an example of a timing chart of input current amplitude I1P, I1N, I2P and I2N, and output voltages VIP, VIN, VQP and VQN of the IV converters in FIG. 6;

FIG. 8 is an exemplary functional block diagram illustrative of a configuration example of an IV converter A221 illustrated in FIG. 2 and an IV converter E421 illustrated in FIG. 4;

FIG. 9 is an exemplary functional block diagram illustrative of the demodulator in a general receiver adopting the direct conversion technology;

FIG. 10 is an exemplary functional block diagram of the demodulator supporting six bands including a band A around 700 MHz, a band B around 800 MHz, a band C around 1.7 GHz, a band D around 2 GHz, a band E around 2.3 GHz, and a band F around 2.5 GHz;

FIG. 11 is an exemplary functional block diagram illustrative of the modulator in a general transmitter adopting the direct conversion technology;

FIG. 12 is an exemplary functional block diagram of the modulator supporting the six bands including a band A around 700 MHz, a band B around 800 MHz, a band C around 1.7 GHz, a band D around 2 GHz, a band E around 2.3 GHz, and a band F around 2.5 GHz;

FIG. 13 is a table illustrative of an example of band combinations used in two regions out of the six bands including the band A around 700 MHz, the band B around 800 MHz, the band C around 1.7 GHz, the band D around 2 GHz, the band E around 2.3 GHz, and the band F around 2.5 GHz;

FIG. 14 is a table illustrative of an example of the band combinations used in three regions out of the six bands including the band A around 700 MHz, the band B around 800 MHz, the band C around 1.7 GHz, the band D around 2 GHz, the band E around 2.3 GHz, and the band F around 2.5 GHz;

FIG. 15 is a table illustrative of a list of the bands corresponding to respective four sets of the input terminals or the output terminals in order to support all of the bands used in each of a region a, a region b, and a region c in FIG. 14 by use of the four sets of the input terminals or the output terminals;

FIG. 16 is a diagram illustrative of a circuit configuration of a demodulator 500 supporting all of the bands used in the respective region a, region b and region c illustrated in FIG. 14, in which one voltage-controlled oscillating circuit is added to the demodulator illustrated in FIG. 10; and

FIG. 17 is a circuit configuration of a modulator 600 supporting all of the bands used in the respective region a, region b, and region c illustrated in FIG. 14, in which one voltage-controlled oscillating circuit is added to the modulator illustrated in FIG. 12.

### DESCRIPTION OF EMBODIMENTS

An embodiment of the present invention will be described below with reference to the attached drawings. The present invention will be clarified by the following description.

First, a demodulator according to an embodiment of the present invention will be described.

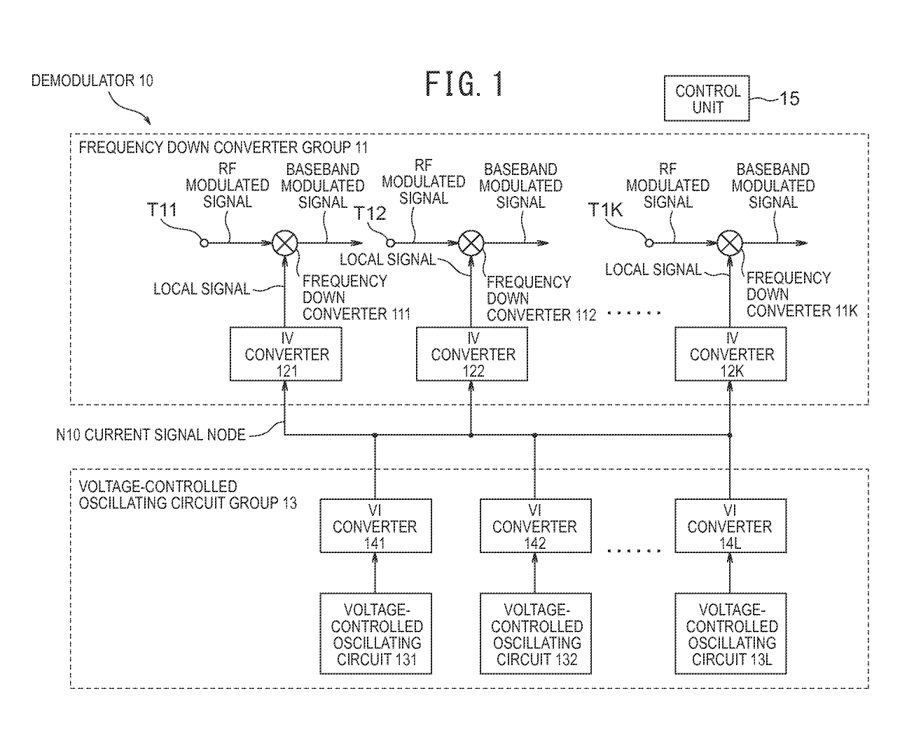

FIG. 1 is an exemplary functional block diagram illustrative of the demodulator according to the embodiment of the present invention.

A demodulator 10 in FIG. 1 includes a frequency down converter group 11, a voltage-controlled oscillating circuit group 13, and a control unit 15.

The frequency down converter group 11 includes K frequency down converters 111 to 11K, and K IV converters 121 to 12K which generate K sets of local signals to be received by the respective frequency down converters 111 to 11K. The voltage-controlled oscillating circuit group 13 includes L voltage-controlled oscillating circuits 131 to 13L, and L VI converters 141 to 14L which convert respective output voltage signals of the voltage-controlled oscillating circuits 131 to 13L into current signals. Here, K and L are arbitrary natural numbers.

It is noted that the frequency down converter group 11 and the voltage-controlled oscillating circuit group 13 are understood as being distinguished each other functionally, and expressed in different names, but this does not mean that both are demanded to be configured separately in the implementation.

The demodulator 10 includes K sets of input terminals T11 to T1K corresponding to the K frequency down converters 111 to 11K of the frequency down converter group 11. RF modulated signals of any combination of the bands can be distributed to the K sets of input terminals T11 to T1K and received thereby.

By using one of the L voltage-controlled oscillating circuits 131 to 13L of the voltage-controlled oscillating circuit group 13, it is possible to generate any of oscillating signals having frequencies capable of covering all of the bands supported by the demodulator 10. Allocation of a frequency range supported by each of the L voltage-controlled oscillating circuits 131 to 13L is determined in consideration of characteristics such as power consumption, device size, and noise power.

The output signals of the L voltage-controlled oscillating circuits 131 to 13L of the voltage-controlled oscillating circuit group 13 are received by the L VI converters 141 to 14L, respectively.

The K IV converters 121 to 12K of the frequency down converter group 11 respectively generate K local signals to be received by the K frequency down converter 111 to 11K. The L VI converters 141 to 14L and the K IV converters 121 to 12K are connected via a common current signal node N10.

Depending on the band of the received RF modulated signal, one set of the voltage-controlled oscillating circuit and the VI converter is selected as the set to be actuated from among the L sets of the voltage-controlled oscillating circuits 131 to 13L and the VI converters 141 to 14L. Further, depending on the input terminal of receiving the RF modulated signals out of the input terminals T11 to T1K, one set of the frequency down converter and the IV converter is selected as the set to be actuated from among the K sets of the frequency down converter 111 to 11K and the IV converters 121 to 12K.

The band to be received is set, for example, by a user at the control unit 15. For each of the input terminals, a band type of the RF modulated signal to be received at the input terminal, the frequency down converter and the IV converter for performing processes to the RF modulated signal received at the input terminal, and the voltage-controlled oscillating circuit and the VI converter are stored in the control unit 15 in a manner that specifies the correspondence relationship among the input terminal, the band type, the frequency down converter, the IV converter, voltage-controlled oscillating circuit and the VI converter. Further, in the control unit 15, when the band to be received is designated by the user, the frequency down converter, the IV converter, the voltage-controlled oscillating circuit, and the VI converter corresponding to the designated band and to be actuated are specified based on the above correspondence relationship stored in the control unit. Then, the specified circuits are selected as the circuits to be actuated.

It is noted that the voltage-controlled oscillating circuits, the VI converters, the frequency down converters, and the IV converters are configured to be actuated when selected as the circuits to be actuated by the control unit 15, and configured to be stopped when not selected as such.

Further, the VI converters 141 to 14L electrically connected with the IV converters 121 to 12K via the common current signal node N10 are configured so as not to send electric current from the current signal node N10 to a ground of the VI converter not selected as the converter to be actuated. Further, the IV converters 121 to 12K are configured such that an electric current does not flows to the current signal node N10, the electric current being supplied from the power source to the IV converter not selected as the converter to be actuated.

Next, a description will be given for an example in which the signals of all of the bands used in the region a, the region b and the region c illustrated in FIG. 14 are supported by use of the demodulator 10.

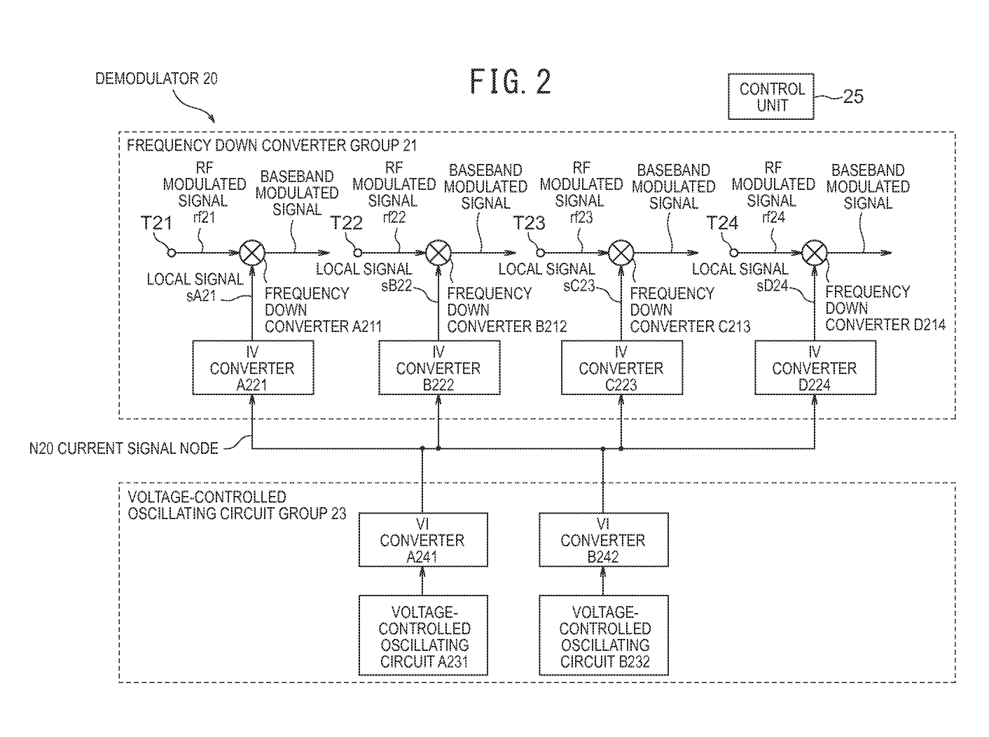

A demodulator 20 illustrated in FIG. 2 is the demodulator 10 in FIG. 1 in the case where K=4 and L=2.

The demodulator 20 includes a frequency down converter group 21, a voltage-controlled oscillating circuit group 23, and a control unit 25 for controlling these components. The frequency down converter group 21, the voltage-controlled oscillating circuit group 23, and the control unit 25 have the same functional configuration as the frequency down converter group 11, the voltage-controlled oscillating circuit group 13, and the control unit 15 in the demodulator 10 illustrated in FIG. 1 except for that the numbers of the frequency down converter, the IV converter, the voltage-controlled oscillating circuit, and the VI converter are different.

The frequency down converter group 21 includes four frequency down converters A211, B212, C213 and D214, and four IV converters A221, B222, C223 and D224 generating local signals to be received by the respective frequency down converters.

The voltage-controlled oscillating circuit group 23 includes two voltage-controlled oscillating circuits A231 and B232, and two VI converters A241 and B242 converting the output voltage signals of the respective voltage-controlled oscillating circuits into the current signals.

The RF modulated signal of the band A or the band B is received by the frequency down converter A211 as an RF modulated signal rf21. Further, the RF modulated signal of the band C is received by the frequency down converter B212 as an RF modulated signal rf22, the RF modulated signal of the band D or the band E is received by the frequency down converter C213 as an RF modulated signal rf23, and the RF modulated signal of the band F is received by the frequency down converter D214 as an RF modulated signal rf24. When one of the frequency down converter A211, the frequency down converter B212, the frequency down converter C213 and the frequency down converter D214 is actuated, the three others are stopped.

When the frequency down converter A211 is actuated, the IV converter A221 is actuated and the output signal from the IV converter A221 is converted into a local signal sA21 to be received by the frequency down converter A211.

When the frequency down converter B212 is actuated, the IV converter B222 is actuated and the output signal from the IV converter B222 is converted into a local signal sB22 to be received by the frequency down converter B212.

When the frequency down converter C213 is actuated, the IV converter C223 is actuated and the output signal from the IV converter C223 is converted into a local signal sC23 to be received by the frequency down converter C213.

When the frequency down converter D214 is actuated, the IV converter D224 is actuated and the output signal from the IV converter D224 is converted into a local signal sD24 to be received by the frequency down converter D214.

The voltage-controlled oscillating circuit A231 outputs an oscillating signal having a frequency from approximately 2.8 GHz to approximately 4 GHz. The voltage-controlled oscillating circuit B232 outputs an oscillating signal having the frequency from approximately 4.6 GHz to approximately 5 GHz. In the case where the RF modulated signal of the band A, the band B, the band C or the band D is received, the voltage-controlled oscillating circuit A231 is actuated and the voltage-controlled oscillating circuit B232 is stopped. In the case where the RF modulated signal of the band E or the band F is received, the voltage-controlled oscillating circuit B232 is actuated and the voltage-controlled oscillating circuit A231 is stopped. Further, the VI converter A241 is actuated concurrently with the voltage-controlled oscillating circuit A231, and the VI converter B242 is actuated concurrently with the voltage-controlled oscillating circuit B232.

In other words, the sets of voltage-controlled oscillating circuits and VI converters do not one-to-one correspond to the sets of IV converters and frequency down converters. Instead, the voltage-controlled oscillating circuit is selected to be actuated so as to generate a desired local signal by changing the combination between the frequency of the output signal outputted from the voltage-controlled oscillating circuit and a division ratio of the IV converter in accordance with the frequency range of the band to be supported.

The output voltage signal from the voltage-controlled oscillating circuit A231 is received by the VI converter A241, and the received output voltage signal is converted into the current signal from the voltage signal, and the converted current signal is outputted to the current signal node N20. The output voltage signal of the voltage-controlled oscillating circuit B232 is received by the VI converter B242, the received output voltage signal is converted into the current signal from the voltage signal, and the converted current signal is outputted to the current signal node N20.

The current signal node N20 to which the output terminals of the two VI converters A241 and B242 are connected is a common node, and further the current signal node N20 is connected to all of the output terminals of the IV converter A221, the IV converter B222, the IV converter C223 and the IV converter D224. In other words, the VI converters A241 and B242, the IV converters A221, B222, C223 and D224 are electrically connected to one another via the current signal node N20. It is noted that no electric current flows from the current signal node N20 to the ground of the stopped VI converter.

One of the IV converter A221, the IV converter B222, the IV converter C223 and the IV converter D224 is actuated while the three others are stopped. The electric current does not flow to the current signal node N20 from the power source supplying the power to the stopped IV converters. The electric current flows to the current signal node N20 from the power source supplying to the power the actuated IV converter, and the IV converter converts the current signal of the current signal node N20 into the voltage signal (local signal sA21, local signal sB22, local signal sC23, or local signal sD24).

The IV converter A221 outputs a signal of which frequency is ¼ of the frequency of the signal outputted from the voltage-controlled oscillating circuit A231 or B232. The IV converter B222, the IV converter C223 and the IV converter D224 output a signal of which frequency is ½ of the frequency of the signal outputted from the voltage-controlled oscillating circuit A231 or B232. An implementation example of the VI converter and the IV converter will be described below.

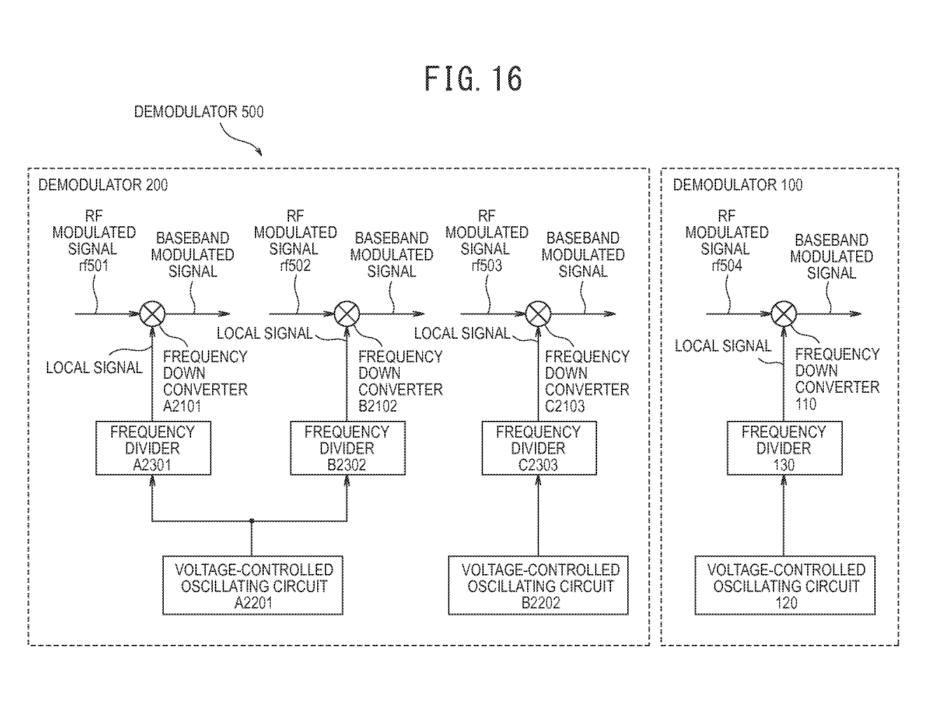

In comparison between the demodulator 20 having the above described configuration and the demodulator 500 adopting the related art illustrated in FIG. 16 and supporting the same number of the plural bands as those supported by the demodulator 20, it is obvious that the demodulator 20 has a smaller circuit size. More specifically, the frequency divider of the demodulator 500 is corresponding to the combination of the IV converter and the VI converter in the demodulator 20. Therefore, the demodulator 20 has two IV converters less and one voltage-controlled oscillating circuit less compared to the demodulator 500. Additionally, while there are the loads of the two frequency dividers at the output of the voltage-controlled oscillating circuit A2201 in the demodulator 500, there is the load of only one VI converter at the output of each of the two voltage-controlled oscillating circuits A231 and B232 in the demodulator 20.

Next, a modulator according to an embodiment of the present invention will be described below.

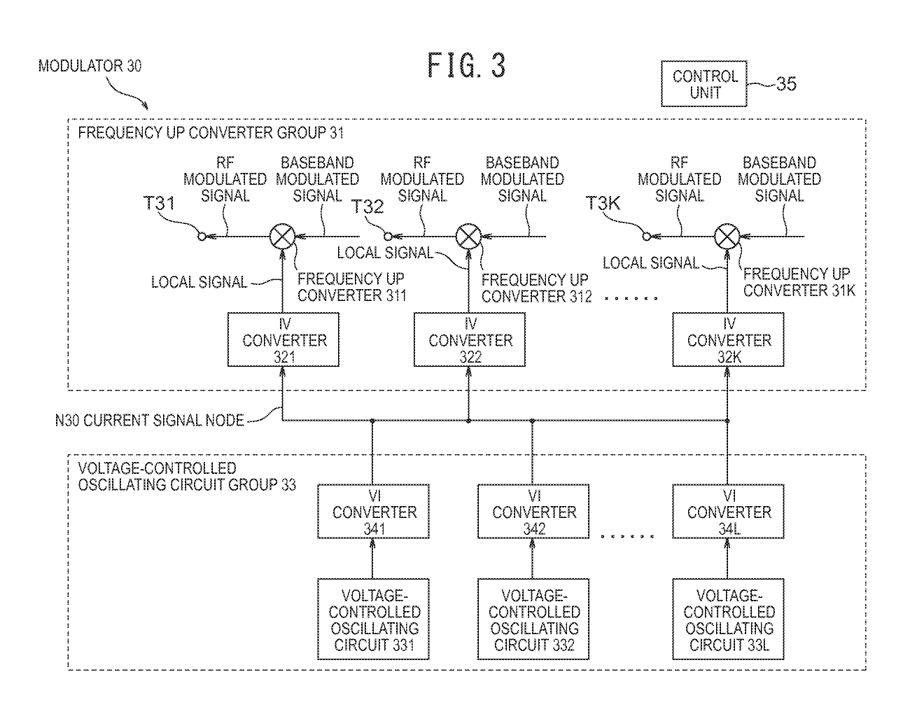

FIG. 3 is an exemplary functional block diagram illustrative of the modulator according to an embodiment of the present invention.

A modulator 30 illustrated in FIG. 3 includes a frequency up converter group 31, a voltage-controlled oscillating circuit group 33, and a control unit 35 for controlling these components.

The frequency up converter group 31 includes K frequency up converters 311 to 31K and K IV converters 321 to 32K generating local signals to be received by the respective frequency up converters 311 to 31K. The voltage-controlled oscillating circuit group 33 includes L voltage-controlled oscillating circuits 331 to 33L and L VI converters 341 to 34L converting output voltage signals of the voltage-controlled oscillating circuits 331 to 33L into current signals. Here, K and L are arbitrary natural numbers. It is noted that the frequency up converter group 31 and the voltage-controlled oscillating circuit group 33 are understood as being distinguished each other functionally, and expressed in different names, but this does not mean that both are demanded to be configured separately in the implementation.

The modulator 30 includes K sets of output terminals T31 to T3K corresponding to the respective K frequency up converters 311 to 31K of the frequency up converter group 31. RF modulated signals of any combination of the bands can be distributed to the K sets of output terminals T31 to T3K and outputted therefrom. By use of one of the L voltage-controlled oscillating circuits 331 to 33L of the voltage-controlled oscillating circuit group 33, it is possible to generate any of oscillating signals having frequencies capable of covering all of the bands supported by the modulator 30. Allocation of a frequency range supported by each of the L voltage-controlled oscillating circuits 331 to 33L handles is determined in consideration of characteristics such as power consumption, device size and noise power.

The respective output signals of the L voltage-controlled oscillating circuits 331 to 33L of the voltage-controlled oscillating circuit group 33 are connected to L VI converters 341 to 34L, and the K IV converters 321 to 32K of the frequency up converter group 31 respectively generate K local signals to be received by the K frequency up converter 311 to 31K.

The L VI converters 341 to 34L and the K IV converters 321 to 32K are electrically connected to a common current signal node N30. Depending on the band of the RF modulated signal to be outputted, one set of the voltage-controlled oscillating circuit and the VI converter is selected as the set to be actuated from among the L sets of voltage-controlled oscillating circuits 331 to 33L and the VI converters 341 to 34L. Further, depending on the output terminal from which the RF modulated signal is outputted, one set of the frequency up converter and the IV converter associated with the output terminal is selected as the set to be actuated from among the K sets of frequency up converter 311 to 31K and the IV converter 321 to 32K.

The band to be outputted is set, for example, by a user at the control unit 35. For each of the output terminals, a band type of the RF modulated signal to be outputted from the output terminal, the frequency up converter and the IV converter for performing processes to the RF modulated signal outputted from the output terminal, and the voltage-controlled oscillating circuit and the VI converter are stored in the control unit 35 in a manner that specifies the correspondence relationship among the output terminal, the band type, the frequency up converter, IV converter, the voltage-controlled oscillating circuit and the VI converter. Further, in the control unit 35, when the band to be transmitted is designated by the user, the frequency up converter, the IV converter, the voltage-controlled oscillating circuit, and the VI converter corresponding to the designated band and to be actuated are specified based on the above stored correspondence relationship. Then, the specified circuits are selected as the circuits to be actuated.

It is noted that these voltage-controlled oscillating circuits, VI converters, the frequency up converter, and the IV converter selected by the control unit 35 as the circuits to be actuated are actuated, and the circuits not selected are stopped.

Further, the VI converters 341 to 34L electrically connected to the IV converters 321 to 32K via the common current signal node N30 are configured so as not to send an electric current from the current signal node N30 to a ground of the VI converters not selected as the converter to be actuated. Further, the IV converters 321 to 32K are configured such that an electric current does not flows to the current signal node N30, the electric current being supplied from a power source to the IV converter not selected as the converter to be actuated.

Next, a description will be given for an example in which the signals of all of the bands used in the region a, the region b and the region c illustrated in FIG. 14 are supported by use of the modulator 30.

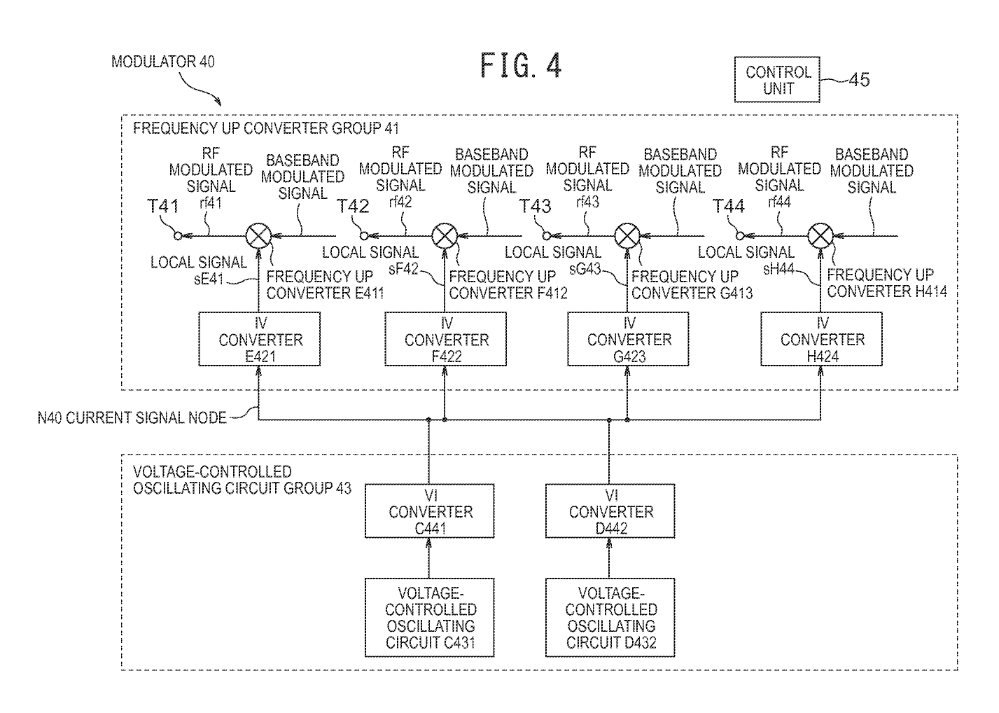

A modulator 40 illustrated in FIG. 4 is the modulator in FIG. 3 in the case of setting K=4 and L=2.

The modulator 40 includes a frequency up converter group 41, a voltage-controlled oscillating circuit group 43, and a control unit 45 for controlling these components. These frequency up converter group 41, voltage-controlled oscillating circuit group 43 and control unit 45 are configured to have the same functions as the frequency up converter group 31, the voltage-controlled oscillating circuit group 33 and the control unit 35 of the modulator 30 in FIG. 3 except for that the number of the frequency up converters, IV converters, the voltage-controlled oscillating circuits, and VI converters are different.

The modulator 40 includes the frequency up converter group 41, voltage-controlled oscillating circuit group 43 and control unit 45. The frequency up converter group 41 includes four frequency up converters E411, F412, G413 and H414, and four IV converters E421, F422, G423 and H424 generating four sets of local signals sE41, sF42, sG43 and sH44 to be received by the respective frequency up converters. The voltage-controlled oscillating circuit group 43 includes two voltage-controlled oscillating circuits C431 and D432, and two VI converters C441 and D442 converting the output voltage signals of the respective voltage-controlled oscillating circuits into the current signals.

The frequency up converter group 41 outputs the RF modulated signal of the band A or the band B as a RF modulated signal rf41, the RF modulated signal of the band C as an RF modulated signal rf42, the RF modulated signal of the band D or the band E as an RF modulated signal rf43, and the RF modulated signal of the band F as an RF modulated signal rf44. When one of the frequency up converter E411, frequency up converter F412, the frequency up converter G413, and the frequency up converter H414 is actuated, the three others are stopped.

When the frequency up converter E411 is actuated, the IV converter E421 is actuated, and the output signal of the IV converter E421 is converted into the local signal sE41 to be received by the frequency up converter E411.

When the frequency up converter F412 is actuated, the IV converter F422 is actuated, and the output signal of the IV converter F422 is converted into the local signal sF42 to be received by the frequency up converter F412.

When the frequency up converter G413 is actuated, the IV converter G423 is actuated, and the output signal of the IV converter G423 is converted into the local signal sG43 to be received by the frequency up converter G413.

When the frequency up converter H414 is actuated, the IV converter H424 is actuated, and the output signal of the IV converter H424 is converted into the local signal sH44 to be received by the frequency up converter H414.

The voltage-controlled oscillating circuit C431 outputs an oscillating signal having the frequency from approximately 2.8 GHz to approximately 4 GHz, and the voltage-controlled oscillating circuit D432 outputs an oscillating signal having the frequency from approximately 4.6 GHz to approximately 5 GHz. In the case of outputting the RF modulated signal of the band A, the band B, the band C or the band D, the voltage-controlled oscillating circuit C431 is actuated and the voltage-controlled oscillating circuit D432 is stopped. In the case of outputting the RF modulated signal of the band E or the band F, the voltage-controlled oscillating circuit D432 is actuated and the voltage-controlled oscillating circuit C431 is stopped. The VI converter C441 is actuated concurrently with the voltage-controlled oscillating circuit C431, and the VI converter D442 is actuated concurrently with the voltage-controlled oscillating circuit D432.

In other words, the sets of the voltage-controlled oscillating circuits and the VI converters do not one-to-one correspond to the sets of the IV converters and the frequency up converters. Instead, the voltage-controlled oscillating circuit is selected to be actuated so as to generate a desired local signal by changing the combination between the frequency of the output signal outputted from the voltage-controlled oscillating circuit and a division ratio of the IV converter in accordance with the frequency range of the band to be supported.

The output signal from the voltage-controlled oscillating circuit C431 is received by the VI converter C441, and the received output signal including the voltage signal is converted into the current signal from the voltage signal, and then outputted to a common current signal node N40. The output signal of the voltage-controlled oscillating circuit D432 is received by the VI converter D442, and the received output signal including the voltage signal is converted into the current signal from the voltage signal, and then outputted to the common current signal node N40.

The current signal node N40 to which the output terminals of the two VI converters C441 and D442 are connected is shared, and also the current signal node N40 is connected to all of the IV converter E421, the IV converter F422, the IV converter G423 and the IV converter H424. It is noted that no electric current flows from the current signal node N40 to the ground of the stopped VI converter.

One of the IV converter E421, the IV converter F422, the IV converter G423, and the IV converter H424 is actuated while three others are stopped. The electric current does not flow to the current signal node N40 from the power source supplying power to the stopped IV converters via these IV converters. The electric current flows to the current signal node N40 from the power source supplying the power to the actuated IV converter, and the current signal of the current signal node N40 is converted into the voltage signal (local signal sE41, local signal sF42, local signal sG43 or local signal sH44).

The IV converter E421 outputs a signal of which frequency is ¼ of the frequency of the signal outputted from the voltage-controlled oscillating circuits C431 or D432, and the IV converter F422, IV converter G423 and IV converter H424 output a signal of which frequency is ½ of the frequency of the signal outputted from the voltage-controlled oscillating circuit C431 or D432.

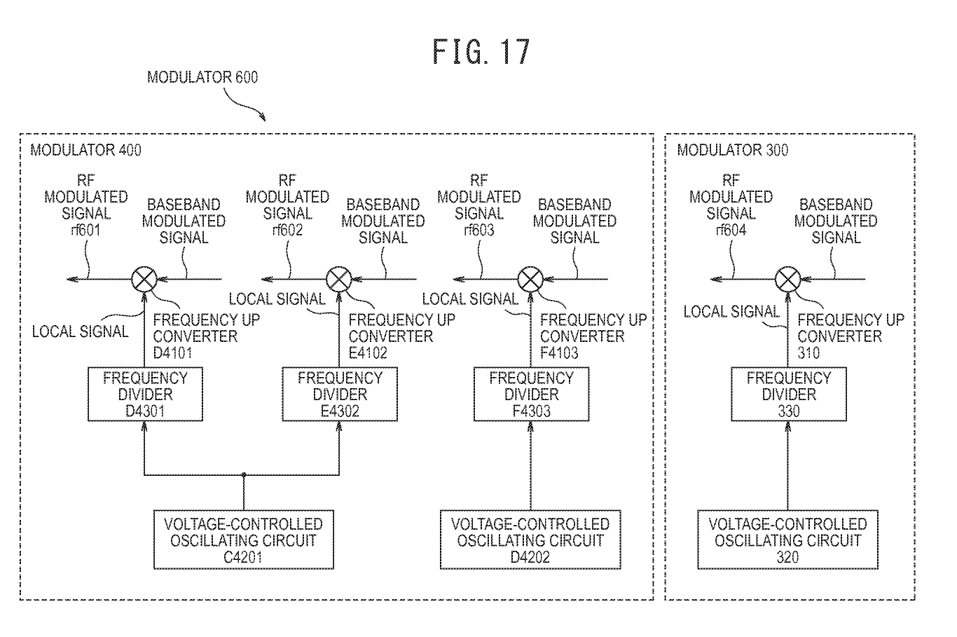

In comparison between the modulator 40 and the modulator 600 adopting the related art illustrated in FIG. 17 and supporting the same plural bands as those supported by the modulator 40, it is obvious that that the modulator 40 has a smaller circuit size. The modulator 40 has two IV converters less and one voltage-controlled oscillating circuit less, compared to the modulator 600. Further, while there are loads of the two frequency dividers D4301 and E4302 at the output of the voltage-controlled oscillating circuit C4201 in the modulator 600, there is the load of only one IV converter at the output of each of the two voltage-controlled oscillating circuits in the modulator 40.

Next, a description will be given for an exemplary configuration of the VI converter and the IV converter implemented by the transistors, included in the demodulators 10 and 20 illustrated in FIGS. 1 and 2 and the modulators 30 and 40 illustrated in FIGS. 3 and 4.

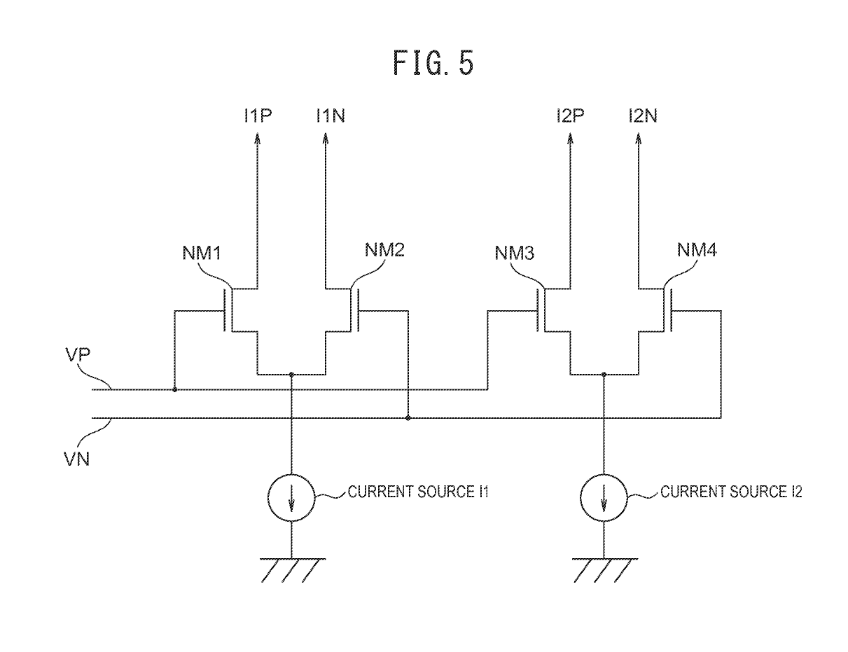

FIG. 5 is a circuit diagram illustrative of an exemplary configuration of the VI converter implemented by the transistors, included in the demodulators 10 and 20 illustrated in FIGS. 1 and 2 and the modulators 30 and 40 illustrated in FIGS. 3 and 4, and these VI converters have the same configuration.

As illustrated in FIG. 5, the VI converter includes the transistors NM1, NM2, NM3 and NM4 formed of N-channel MOS (Metal Oxide Semiconductor) transistors, and current sources I1 and I2.

All of the transistors NM1, NM2, NM3 and NM4 are formed in the same size. Further, the current sources I1 and I2 output the same constant current. Further, the VI converter includes the same two differential pairs as illustrated in FIG. 5. More specifically, sources of the transistors NM1 and NM2 are grounded via the current source I1, and the sources of the transistors NM3 and NM4 are grounded via the current source I2. At gates of the transistor NM1 and NM3, for example, an output differential signal VP on positive side of the differential controlled type voltage-controlled oscillating circuit is received. At gates of the transistor NM2 and NM4, an output differential signal VN on the negative side of the voltage-controlled oscillation circuit is received.

The electric current does not flow to the current source I1 and current source I2 while the VI converter is stopped. While the VI converter is actuated and the electric current flows to the current source I1 and the current source I2, the output differential signals VP and VN of the voltage-controlled oscillating circuit are received by the two sets of the differential pairs and converted into two pairs of differential current signals I1P and I1N, and I2P and I2N.

Thus, the VI converter is configured such that the respective transistors NM1 to NM4 are controlled by the output differential signals VP and VN from the voltage-controlled oscillating circuit to output the two pairs of the differential current signals I1P and I1N, and I2P and I2N. While the voltage-controlled oscillating circuit is stopped, the transistors NM1 to NM4 are turned off because the output differential signals VP and VN of the voltage-controlled oscillating circuit are not supplied to the transistors NM1 to NM4 of the VI converter being paired with the voltage-controlled oscillating circuit. Therefore, the electric current does not flow to the ground of the VI converter from the common current signal node to which the VI converter is connected.

As a result, the electric current from the current signal node to the ground of the stopped VI converter can be stopped despite the fact that the plural VI converters are connected to the common current signal node. Also, since the VI converter is actuated in accordance with the output differential signals VP and VN from the voltage-controlled oscillating circuit as described above, the VI converter being paired with the voltage-controlled oscillating circuit can be stopped by stopping the voltage-controlled oscillating circuit by the control unit.

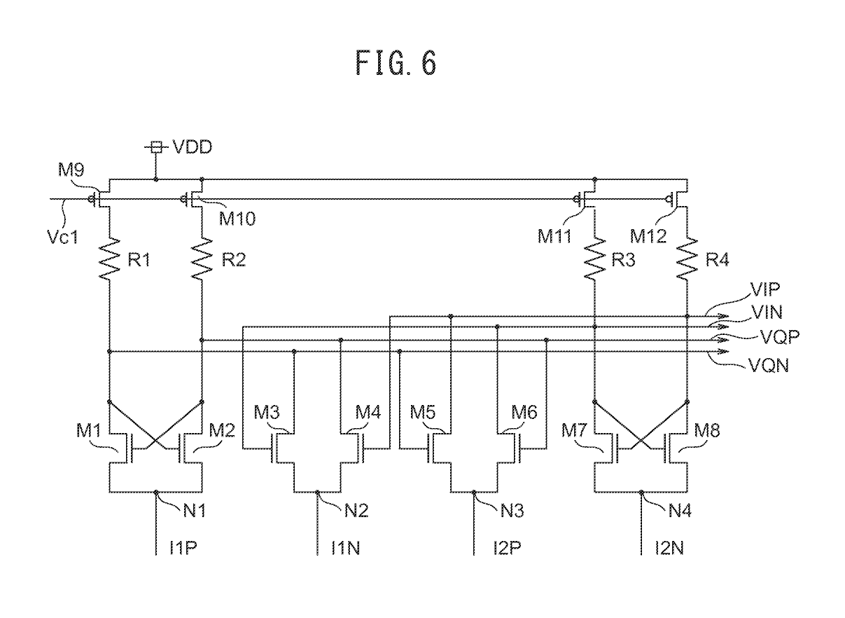

FIG. 6 is a circuit diagram illustrative of an exemplary configuration in which the IV converter B222, the IV converter C223 and the IV converter D224 illustrated in FIG. 2 and the IV converter F422, the IV converter G423 and the IV converter H424 illustrated in FIG. 4 are implemented by the transistors, and these IV converters have the same configuration.

As illustrated in FIG. 6, the IV converter includes transistors M9, M10, M11 and M12 formed of P-channel MOS transistors, load resistors R1, R2, R3 and R4, and transistors M1, M2, M3, M4, M5, M6, M7 and M8 formed of the N-channel MOS transistors.

The IV converter illustrated in FIG. 6 outputs a difference between the output voltages VIP and VIN as a voltage signal I, and a difference between the output voltages VQP and VQN as a voltage signal Q.

The transistors M9, M10, M11 and M12 are actuated and stopped by a control signal Vc1 and operate as switches to connect a power source VDD with the load resistors R1, R2, R3 and R4. While the IV converter is actuated, the transistors M9 to M12 are turned ON and the electric current flows from the power source VDD, and while the IV converter is stopped, the transistors are turned OFF and the electric current from the power source VDD is stopped.

The control signal Vc1 is outputted from the control unit, and the transistors M9 to M12 are controlled by the control signal. When the IV converter is stopped, the transistors M9 to M12 are turned OFF, so that the electric current supplied to the stopped IV converter from the power source is stopped from flowing into the current signal node via the IV converter.

In the following, operations when the transistors M9, M10, M11 and M12 are turned ON will be described. The transistors M1, M2, M3, M4, M5, M6, M7 and M8 are formed in the same size. Further, all of the load resistors R1, R2, R3 and R4 have the same resistance value.

The IV converter illustrated in FIG. 6 has a general circuit configuration. The type of the transistors M1, M2, M3, M4, M5, M6, M7 and M8 may be bipolar transistor, but in this case, the N-channel MOS transistor is used for convenience of explanation.

The transistors M7 and M8 and the transistors M5 and M6 respectively make pairs, and the pairs determine potential of the VIP and VIN.

Both of sources of the transistors M7 and M8 are connected to a node N4, and the node N4 is connected to the output terminal of the VI converter illustrated in FIG. 5, from which the differential current signal I2N is outputted. Both of sources of the transistors M5 and M6 are connected to a node N3, and the node N3 is connected to the output terminal of the VI converter illustrated in FIG. 5, from which the differential current signal I2P is outputted.

The VIP is a drain voltage of the transistors M5 and M8, and the drain of the transistors M5 and M8 is connected to one end of the load resistor R4. The other end of the load resistor R4 is connected to the power source VDD via the transistor M12. The VIN is the drain voltage of the transistors M6 and M7, and the drain of the transistors M6 and M7 is connected to one end of the load resistor R3. The other end of the load resistor R3 is connected to the power source VDD via the transistor M11.

The differential current signals I2P and I2N are inverted to each other. When the amplitude waveform of the differential current signal I2P is upward convex, more specifically, when the electric current in the pair of transistors M5 and M6 is larger than the electric current in the pair of the transistors M7 and M8, the potential of the VIP and VIN is determined by the operation of the transistors M5 and M6. In contrast, when the amplitude waveform of the differential current signal I2N is upward convex, the potential of the VIP and VIN is determined by the operation of the transistors M7 and M8.

The potential of the VQP and VQN is determined by the pair of the transistors M1 and M2 as well as the pair of the transistors M3 and M4.

Both of sources of the transistors M1 and M2 are connected to a node N1, and the node N1 is connected to the output terminal of the VI converter illustrated in FIG. 5, from which the differential current signal I1P is outputted. Both of sources of the transistors M3 and M4 are connected to a node N2, and the node N2 is connected to the output terminal of the VI converter illustrated in FIG. 5, from which the differential current signal I1N is outputted.

The drain voltage of the transistors M2 and M4 is the output voltage VQP, and the drain of the transistors M2 and M4 is connected to one end of the load resistor R2. The other end of the load resistor R2 is connected to the power source VDD via the transistor M10.

The drain voltage of the transistors M1 and M3 is the output voltage VQN, and further the drain of the transistors M1 and M3 is connected to one end of the load resistor R1. The other end of the load resistor R1 is connected to the power source VDD via the transistor M9.

The drain voltage of the transistors M2 and M4, namely the output voltage VQP, is received at the gate of the transistor M1. The drain voltage of the transistors M1 and M3, namely the output voltage VQN, is received at the gate of the transistor M2. The output voltage VIN is received at the gate of the transistor M3. The output voltage VIP is received at the gate of the transistor M4. The output voltage VQN is received at the gate of the transistor M5. The output voltage VQP is received at the gate of the transistor M6. The drain voltage of the transistors M5 and M8, namely the output voltage VIP, is received at the gate of the transistor M7. The drain voltage of the transistors M6 and M7, namely the output voltage VIN, is received at the gate of the transistor M8.

Here, the differential current signals I1P and I1N supplied from the VI converter are inverted to each other. When the amplitude waveform of the differential current signal I1P is upward convex, more specifically, when the electric current in the pair of the transistors M1 and M2 is larger than the electric current in the pair of the transistors M3 and M4, the potential of the output voltages VQP and VQN is determined by the operation of the transistors M1 and M2. In contrast, when the amplitude waveform of the differential current signal I1N is upward convex, the potential of the output voltages VQP and VQN is determined by the operation of the transistors M3 and M4.

In the IV converter having the above described configuration, firstly, a description will be given focusing on the operation of the transistors M7 and M8 when the amplitude waveform of the differential current signals I1N and I2N is upward convex.

As illustrated in FIG. 6, the drain voltage of the transistor M8, namely the output voltage VIP, is the gate voltage of the transistor M7, and the drain voltage of the transistor M7, namely the output voltage VIN, is the gate voltage of the transistor M8.

When the VIP corresponding to the drain voltage of the transistor M8 becomes high, the voltage between the gate and source of the transistor M7 becomes high, therefore the electric current flowing in the transistor M7, namely the electric current flowing in the load resistor R3 is increased. Thus, the potential (VIN) of the drain of the transistor M7 becomes low, accordingly, the voltage between the gate and source of the transistor M8 becomes low. Then, the electric current flowing in the transistor M8, namely the electric current flowing in the load resistor R4 is reduced. As a result, the drain voltage of the transistor M8, namely the potential of the output voltage VIP is increased. Therefore, when the amplitude waveform of the differential current signal I2N is upward convex, the potential of the output voltage VIP is kept in a high state and the potential of the output voltage VIN is kept in a low state.

Next, a description will be given focusing on the operation of the transistors M3 and M4 when the amplitude waveform of the differential current signals I1N and I2N is upward convex.

The gate voltage of the transistor M4 is the output voltage VIP, and the gate voltage of the transistor M3 is the output voltage VIN. As described above, since the output voltage VIP is higher than VIN, in the case where the amplitude waveform of the differential current signals I1N and I2N is upward convex, the transistor M4 comes to have the higher voltage between the source and gate than the transistor M3 does. Accordingly, the electric current flowing in the transistor M4 is larger than the electric current in the transistor M3. In other word, the potential of the output voltage VQP becomes low and the potential of the VQN becomes high because the electric current in the load resistor R2 becomes larger than the electric current in the load resistor R1.

Next, a description will be given focusing on the transistors M1 and M2 in the case where the amplitude of the differential current signals I1N and I2N supplied from the VI converter lowers and the amplitude waveform of the differential current signals I1P and I2P is upward convex.

The drain voltage of the transistor M1, namely the output voltage VQN, is the gate voltage of the transistor M2. The drain voltage of the transistor M2, namely the output voltage VQP, is the gate voltage of the transistor M1.

In the case where the amplitude waveform of the differential current signals I1P and I2P is upward convex, the potential of the drain voltage (namely output voltage) VQN of the transistor M2 becomes low when the potential of the drain voltage (namely output voltage) VQP of the transistor M1 becomes high. Conversely, the potential of the drain voltage VQN become high when the potential of the drain voltage VQP becomes low in the same manner as the transistors M7 and M8. Therefore, the potential of the drain voltage VQP is kept in a low state and the potential of the drain voltage VQN is kept in a high state.

Next, a description will be given focusing on the operation of the transistors M5 and M6 when the amplitude waveform of the differential current signals I1P and I2P is upward convex.

The gate voltage of the transistor M5 is the output voltage VQN, and the gate voltage of the transistor M6 is the output voltage VQP. As described above, since the drain voltage VQN is larger than the drain voltage VQP, the transistor M5 has the higher voltage between the gate and source than the transistor M6 does, and the electric current flowing in the transistor M5 becomes larger than the electric current flowing in the transistor M6. In other word, the potential of the output voltage VIP becomes low and the potential of the VIN becomes high because the electric current in the load resistor R4 becomes larger than the electric current in the load resistor R3.

Summarizing the above, both the pair of the output voltages VIP and VIN and the pair of VQP and VQN have the phases inverted each other. The pair of the output voltages VIP and VIN are inverted at the timing when the amplitude waveform of the differential current signals I1P and I2P rises so as to present a upward convex shape after a downward convex shape, and the pair of VQP and VQN are inverted at the timing when the amplitude waveform of the differential current signals I1N and I2N rises so as to present a upward convex shape after a downward convex shape.

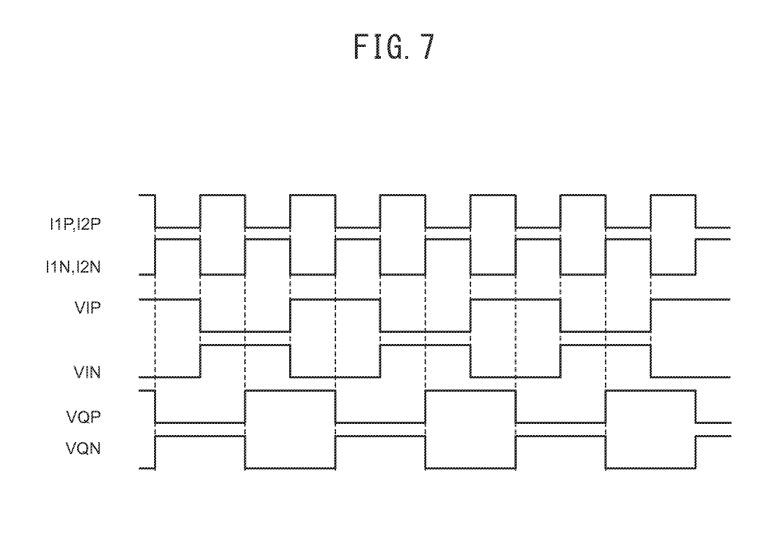

FIG. 7 is a timing chart of the differential current signals I1P and I1N, and I2P and I2N to be received by the IV converter, and the output voltages VIP, VIN, VQP and VQN. Here, waveforms are rectangular shaped for simplification.

The differential current signals I1P, I1N, I2P and I2N are obtained by converting the output voltage signals of the voltage-controlled oscillating circuit into the current signals in the VI converter. Accordingly, the difference between I1P and I1N and the difference between I2P and I2N have the same phase as that of the differential signal of the voltage-controlled oscillating circuit.

Therefore, the voltage signal I and voltage signal Q obtained by converting the differential current signals I1P, I1N, and I2P, I2N have a relation in which the phase of the voltage signal I is shifted from that of the voltage signal by 90 degrees, and the frequency of the voltage signals I and Q are ½ of the oscillation frequency of the voltage-controlled oscillating circuit.

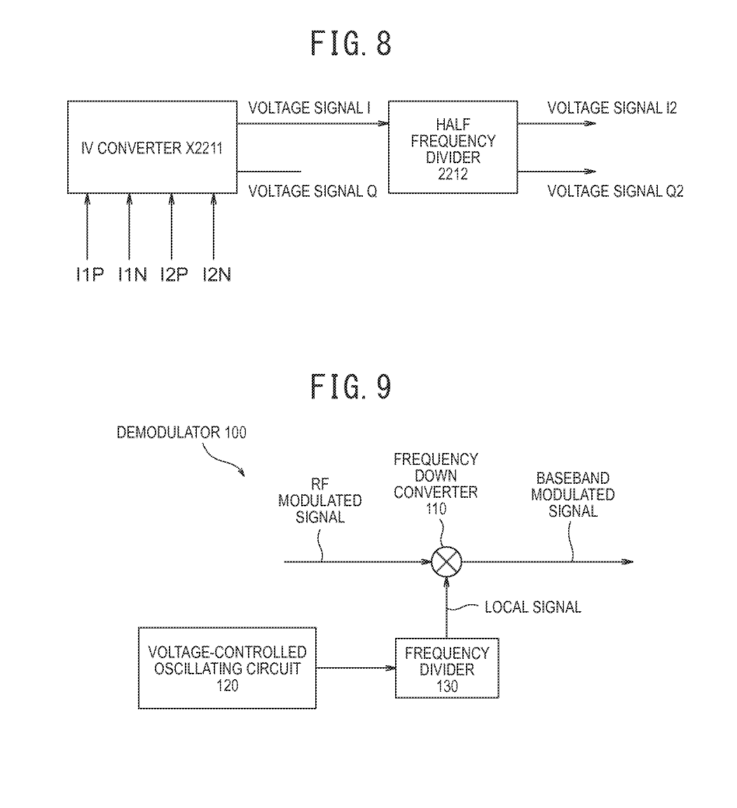

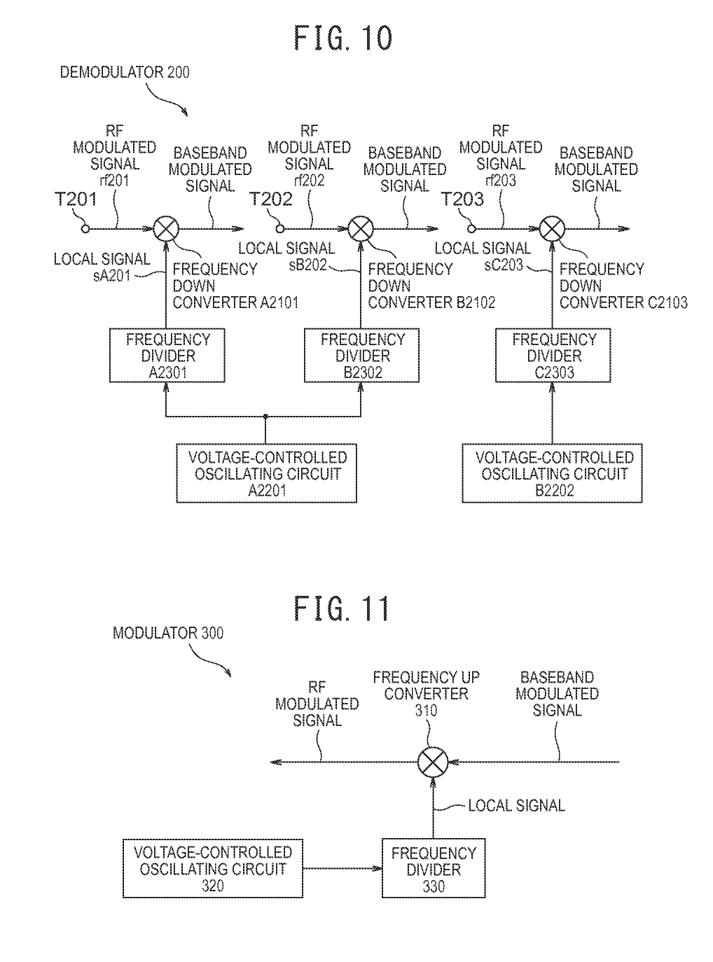

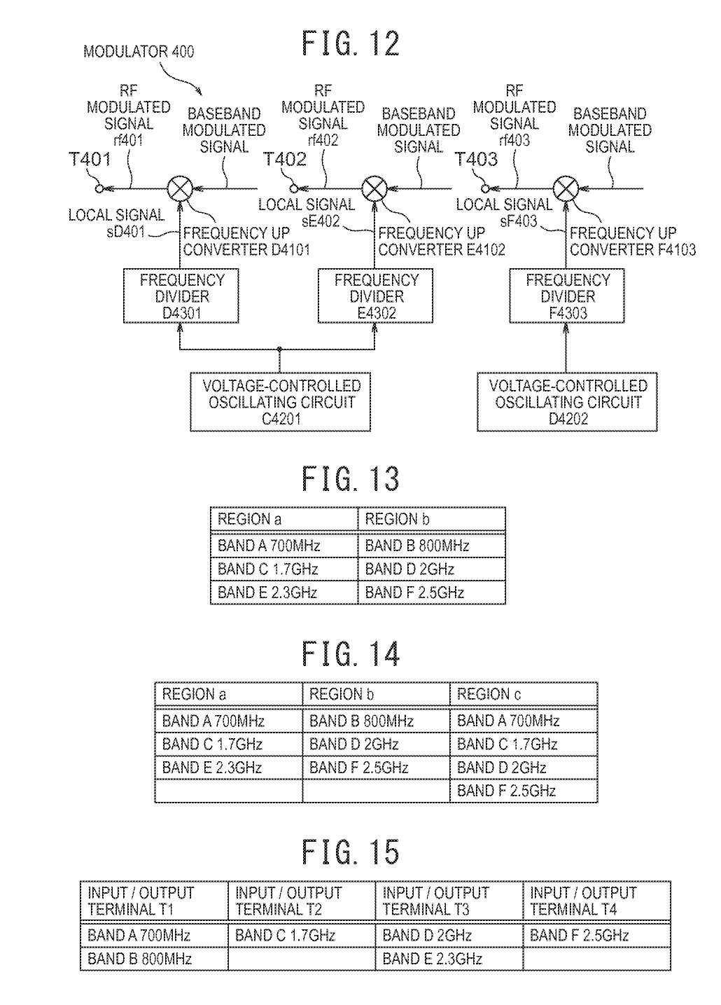

FIG. 8 is a functional block diagram illustrative of an exemplary configuration of the IV converter A221 illustrated in FIG. 2 and the IV converter E421 illustrated in FIG. 4. Here, a description will be given for the IV converter A221 as the IV converter A221 and the IV converter E421 have the same configuration.

The IV converter A221 in FIG. 8 includes an IV converter X 2211 and a half frequency divider 2212. The IV converter X 2211 has the same configuration as the IV converter illustrated in FIG. 6. The voltage signal I (output voltage VIP, VIN) outputted from the IV converter X 2211 is received by the half frequency divider 2212 and the frequency is divided by two. At this time, the voltage signal Q (output voltage VQP, VQN) may be also received by the half frequency divider 2212.

In the case where the signal to be demodulated or modulated is an IQ orthogonal modulated signal, the half frequency divider 2212 may be the circuit formed by connecting the VI converter illustrated in FIG. 5 to the IV converter illustrated in FIG. 6. In this case, a voltage signal I2 (output voltage VIP′, VIN′) and a voltage signal Q2 (output voltage VQP′, VQN′) outputted from the half frequency divider 2212 are in a relation in which the phase of the voltage signal I2 is shifted from that of the voltage signal Q2 by 90 degrees, and the frequency of the voltage signals I2 and Q2 are ¼ of the oscillated frequency of the voltage-controlled oscillating circuit.

As described above, the demodulator and the modulator supporting multiple bands can be realized, in which the IV converter and the VI converter are electrically connected to the common current signal node, and the local signal of a desired frequency is generated by changing the combination of the pairs to be actuated among the pairs of the frequency down converter or the frequency up converter and the IV converter and the pairs of the voltage-controlled oscillating circuit and the VI converter.

Particularly, as described above using the demodulator 20 illustrated in FIG. 2 and the modulator 40 illustrated in FIG. 4, in order to allocate the plural bands including the band D (around 2 GHz) and the band E (around 2.3 GHz) to one input terminal or one output terminal, and to obtain the local signals sC23 and sG43 corresponding to the RF modulated signals (for example, 2 GHz to 2.3 GHz) of the plural bands, even if it is necessary to use the plural voltage-controlled oscillating circuits so as to generate an oscillating signal having a frequency from approximately 2.8 GHz to approximately 4 GHz, and from approximately 4.6 GHz to approximately 5 GHz, that is, it is necessary to obtain the output signal covering the plural bands from the voltage-controlled oscillating circuit, the local signal corresponding to the band can be generated by changing the combination between the oscillated frequency of the voltage-controlled oscillating circuit and the division ratio of the IV converter in accordance with the band types, without increasing an extra voltage-controlled oscillating circuit and without providing any branched outputs of the plural voltage-controlled oscillating circuits and giving any redundant output load, as described above.

Further, in the case where the band to be supported is increased and the input terminal or output terminal for receiving or outputting a signal of the band is increased, it is possible to deal with the increase by changing the value K, or both values K and L in the demodulator 10 illustrated in FIG. 1 and the modulator 30 illustrated in FIG. 3.

In the case where the frequency of the band received by the input terminal corresponding to a newly added band or the frequency of the band outputted from the newly added output terminal cannot be supported by the existing voltage-controlled oscillating circuit or cannot be supported by expanding the oscillator bandwidth relatively simply, the voltage-controlled oscillating circuit is needed to be inevitably increased regardless of the circuit configuration proposed in the present invention. In such a case, both K and L are needed to be incremented by one according to the present invention, and the circuit size to be increased is same as the related art.

However, in the case where the frequency of the band received by the newly added input terminal or the frequency of the band outputted from the newly added output terminal can be supported by the existing voltage-controlled oscillating circuit or can be by expanding the oscillator bandwidth relatively simply, L may be kept as “2” and K may be incremented by one, for example. In other words, the voltage-controlled oscillating circuit is not increased and the output load of the existing voltage-controlled oscillating circuit has no change.

Note that the scope of the present invention is not limited to the exemplary embodiments illustrated in the drawings and described above and may include all embodiments that will bring equivalent effects intended by the present invention. Furthermore, the scope of the present may be defined by any desired combination of the specific characteristics of all the features discloses herein.

### REFERENCE SIGNS LIST

10 Demodulator
11 Frequency down converter group
13 Voltage-controlled oscillating circuit group
15 Control unit
111 to 11K Frequency down converter
121 to 12K IV converter
131 to 13L Voltage-controlled oscillating circuit
141 to 14L VI converter
20 Demodulator
21 Frequency down converter group
23 Voltage-controlled oscillating circuit group
25 Control unit
211 Frequency down converter A
212 Frequency down converter B
213 Frequency down converter C
214 Frequency down converter D
221 IV converter A
222 IV converter B
223 IV converter C
224 IV converter D
231 Voltage-controlled oscillating circuit A
232 Voltage-controlled oscillating circuit B
241 VI converter A
242 VI converter B
30 Modulator
31 Frequency up converter group
33 Voltage-controlled oscillating circuit group
35 Control unit
311 to 31K Frequency up converter
321 to 32K IV converter
331 to 33L Voltage-controlled oscillating circuit
341 to 34L VI converter
40 Modulator
41 Frequency up converter group
43 Voltage-controlled oscillating circuit group
45 Control unit
411 Frequency up converter E
412 Frequency up converter F
413 Frequency up converter G
414 Frequency up converter H
421 IV converter E
422 IV converter F
423 IV converter G
424 IV converter H
431 Voltage-controlled oscillating circuit C
432 Voltage-controlled oscillating circuit D
441 VI converter C
442 VI converter D
2211 IV converter X
2212 half frequency divider
100 Demodulator
110 Frequency down converter
120 Voltage-controlled oscillating circuit
130 Frequency divider
200 Demodulator
2101 Frequency down converter A
2102 Frequency down converter B
2103 Frequency down converter C
2201 Voltage-controlled oscillating circuit A
2202 Voltage-controlled oscillating circuit B
2301 Frequency divider A
2302 Frequency divider B
2303 Frequency divider C
300 Modulator
310 Frequency up converter
320 Voltage-controlled oscillating circuit
330 Frequency divider
400 Modulator
4101 Frequency up converter D
4102 Frequency up converter E
4103 Frequency up converter F
4201 Voltage-controlled oscillating circuit C
4202 Voltage-controlled oscillating circuit D
4301 Frequency divider D
4302 Frequency divider E
4303 Frequency divider F

1. A demodulator, comprising:
a frequency down conversion unit including a plurality of input terminals at which a plurality of RF modulated signals is received, respectively, a plurality of frequency down converters provided for the plurality of input terminals, respectively, and a plurality of IV converters provided for the plurality of frequency down converters, respectively;
a voltage-controlled oscillation unit including a plurality of voltage-controlled oscillating circuits and a plurality of VI converters provided for the plurality of voltage-controlled oscillating circuits, respectively; and
a node electrically connected to the plurality of IV converters and the plurality of VI converters.

2. The demodulator according to claim 1, wherein
one IV converter among the plurality of IV converters receives a current signal from one VI converter among the plurality of VI converters via the node, the one IV converter being paired with one of the plurality of frequency down converters corresponding to one of the plurality of input terminals at which the RF modulated signal is received, the one VI converter being paired with one of the plurality of voltage-controlled oscillating circuits for generating a voltage signal having a frequency corresponding to the received RF modulated signal.

3. The demodulator according to claim 2, comprising:
a control unit configured to output a control signal,
wherein the control signal actuates the one IV converter among the plurality of IV converters and the one VI converter among the plurality of VI converters, the one IV converter being paired with the one of the plurality of frequency down converters corresponding to the one of the plurality of input terminals at which the RF modulated signal is received, the one VI converter being paired with the one of the plurality of voltage-controlled oscillating circuits for generating the voltage signal having the frequency corresponding to the received RF modulated signal, and
the control signal stops an IV converter other than the one IV converter among the plurality of IV converters and a VI converter other than the one VI converter among the plurality of VI converters.

4. The demodulator according to claim 1, wherein the plurality of RF modulated signals have different frequency bands, respectively.

5. The demodulator according to claim 1, wherein the plurality of voltage-controlled oscillating circuits generate voltage signals having carrier frequencies corresponding to respective frequency bands of the plurality of RF modulated signals received by the frequency down conversion unit or frequencies corresponding to an even multiple of the carrier frequencies.

6. The demodulator according to claim 1, wherein the plurality of IV converter includes a first IV conversion unit configured to reduce a frequency of the current signal to half, and a second IV conversion unit configured to reduce the frequency of the current signal to quarter.

7. The demodulator according to claim 1, wherein the plurality of voltage-controlled oscillating circuits include a first voltage-controlled oscillating circuit and a second voltage-controlled oscillating circuit configured to generate voltage signals having frequencies of different bands, respectively,
the plurality of input terminals include at least one input terminal, the RF modulated signals of two or more frequency bands being received at each of the at least one input terminal, the first voltage-controlled oscillating circuit generates the voltage signal having a carrier frequency corresponding to a frequency band of a first RF modulated signal or a frequency corresponding to an even multiple of the carrier frequency, and
the second voltage-controlled oscillating circuit generates the voltage signal having a carrier frequency corresponding to a frequency band of a second RF modulated signal or a frequency corresponding to an even multiple of the carrier frequency.

8. A modulator, comprising:
a frequency up conversion unit including a plurality of output terminals for outputting a plurality of RF modulated signals, respectively, a plurality of frequency up converters provided for the plurality of output terminals, respectively, and a plurality of IV converters provided for the plurality of frequency up converters, respectively;
a voltage-controlled oscillation unit including a plurality of voltage-controlled oscillating circuits and a plurality of VI converters provided for the plurality of voltage-controlled oscillating circuits, respectively; and
a node electrically connected to the plurality of IV converters and the plurality of VI converters.

9. The modulator according to claim 8, wherein
one IV converter among the plurality of IV converters receives a current signal from one VI converter among the plurality of VI converters via the node, the one IV converter generating a local signal having a frequency corresponding to the RF modulated signal to be outputted, the one VI converter being paired with one of the plurality of voltage-controlled oscillating circuits for generating a voltage signal having a frequency corresponding to the RF modulated signal to be outputted.

10. The demodulator according to claim 9, comprising:
a control unit configured to output a control signal,
wherein the control signal actuates the one IV converter among the plurality of IV converters and the one VI converter among the plurality of VI converters, the one IV converter generating the local signal having the frequency corresponding to the RF modulated signal to be outputted, the one VI converter being paired with the one of the plurality of voltage-controlled oscillating circuits for generating the voltage signal having the frequency corresponding to the RF modulated signal to be outputted, and
the control signal stops an IV converter other than the one IV converter among the plurality of IV converters and a VI converter other than the one VI converter among the plurality of VI converters.

11. The modulator according to claim 8, wherein
the plurality of RF modulated signals have different frequency bands, respectively.

12. The modulator according to claim 8, wherein
the plurality of voltage-controlled oscillating circuits generate voltage signals having carrier frequencies corresponding to respective frequency bands of all of the RF modulated signals to be outputted from the frequency up conversion unit or frequencies corresponding to an even multiple of the carrier frequencies.

13. The modulator according to claim 8, wherein
the plurality of IV converter includes a first IV conversion unit configured to reduce a frequency of the current signal to half, and a second IV conversion unit configured to reduce the frequency of the current signal to quarter.

14. The modulator according to claim 8, wherein
the plurality of voltage-controlled oscillating circuits include a first voltage-controlled oscillating circuit and a second voltage-controlled oscillating circuit configured to generate voltage signals having frequencies of different bands, respectively,
the plurality of output terminals include at least one output terminal, the RF modulated signals of two or more frequency bands being outputted at each of the at least one output terminal,
the first voltage-controlled oscillating circuit generates the voltage signal having a carrier frequency corresponding to a frequency band of a first RF modulated signal or a frequency corresponding to an even multiple of the carrier frequency, and
the second voltage-controlled oscillating circuit generates the voltage signal having a carrier frequency corresponding to a frequency band of a second RF modulated signal or a frequency corresponding to an even multiple of the carrier frequency.
